(19) United States
(12) Patent Application Publication
(10) Pub. No.: US 2019/0296042 A1
(43) Pub. Date: Sep. 26, 2019

(54) SEMICONDUCTOR MEMORY DEVICE AND METHOD FOR MANUFACTURING SAME

(71) Applicant: TOSHIBA MEMORY CORPORATION, Minato-ku (JP)

(72) Inventors: Hiroshi NAKAKI, Yokkaichi (JP); Kotaro FUJII, Yokkaichi (JP)

(73) Assignee: TOSHIBA MEMORY CORPORATION, Minato-ku (JP)

(21) Appl. No.: 16/127,500

(22) Filed: Sep. 11, 2018

(30) Foreign Application Priority Data
Mar. 20, 2018 (JP) 2018-052086

(51) Int. Cl. H01L 27/11582; H01L 29/66

(52) U.S. Cl. CPC H01L 27/11582; H01L 29/66833

(57) ABSTRACT

A method for manufacturing a semiconductor memory device includes forming a plurality of connection portions on a plurality of main body portions by filling a semiconductor material into a plurality of second through-holes, and after the forming of the plurality of connection portions, removing the third layer and a remaining portion of the second layer, the remaining portion of the second layer not being removed in the removing of the portion of the second layer.

### CROSS-REFERENCE TO RELATED APPLICATIONS

This application is based upon and claims the benefit of priority from Japanese Patent Application No. 2018-052086, filed on Mar. 20, 2018; the entire contents of which are incorporated herein by reference.

### FIELD

Embodiments relate generally to a semiconductor memory device and a method for manufacturing the same.

### BACKGROUND

A semiconductor memory device has been proposed in which memory cells are arranged three-dimensionally. In such a semiconductor memory device, a stacked body that includes multiple electrode layers functioning as control gates of the memory cells is formed; and channels and charge storage films are formed inside memory holes piercing the stacked body. By forming holes and/or trenches in the upper portion of the stacked body, contacts that are connected to the channels are formed; and the electrode layer of the upper layer is divided. Taper angles easily occur in the holes and/or the trenches in the patterning of such an electrode layer; and it is difficult to downscale the memory cells.

### BRIEF DESCRIPTION OF THE DRAWINGS

FIG. 1 is a plan view showing a semiconductor memory device according to a first embodiment;

FIG. 2 is a cross-sectional view of line A1-A2 of FIG. 1;

FIG. 3 is an enlarged view of region B of FIG. 2;

FIG. 4 is a perspective view showing a portion of the semiconductor memory device according to the first embodiment;

FIG. 5A and FIG. 5B are cross-sectional views showing a method for manufacturing the semiconductor memory device according to the first embodiment;

FIG. 6A and FIG. 6B are cross-sectional views showing a method for manufacturing the semiconductor memory device according to the first embodiment;

FIG. 7 is a plan view showing a method for manufacturing the semiconductor memory device according to the first embodiment;

FIG. 8A and FIG. 8B are cross-sectional views showing a method for manufacturing the semiconductor memory device according to the first embodiment;

FIG. 9A and FIG. 9B are cross-sectional views showing a method for manufacturing the semiconductor memory device according to the first embodiment;

FIG. 10A and FIG. 10B are cross-sectional views showing a method for manufacturing the semiconductor memory device according to the first embodiment;

FIG. 11A and FIG. 11B are cross-sectional views showing a method for manufacturing the semiconductor memory device according to the first embodiment;

FIG. 12 is a plan view showing a method for manufacturing the semiconductor memory device according to the first embodiment;

FIG. 13A and FIG. 13B are cross-sectional views showing a method for manufacturing the semiconductor memory device according to the first embodiment;

FIG. 14A and FIG. 14B are plan views showing a method for manufacturing a semiconductor memory device according to a modification of the first embodiment;

FIG. 15 is a cross-sectional view showing a method for manufacturing a semiconductor memory device according to another modification of the first embodiment;

FIG. 16 is a cross-sectional view showing a semiconductor memory device according to a second embodiment;

FIG. 17A and FIG. 17B are cross-sectional views showing a method for manufacturing the semiconductor memory device according to the second embodiment;

FIG. 18A and FIG. 18B are cross-sectional views showing a method for manufacturing the semiconductor memory device according to the second embodiment;

FIG. 19A and FIG. 19B are cross-sectional views showing a method for manufacturing the semiconductor memory device according to the second embodiment;

FIG. 20A and FIG. 20B are cross-sectional views showing a method for manufacturing the semiconductor memory device according to the second embodiment;

FIG. 21 is a cross-sectional view showing a method for manufacturing the semiconductor memory device according to the second embodiment;

FIG. 22 is a cross-sectional view showing a semiconductor memory device according to a third embodiment;

FIG. 23A and FIG. 23B are cross-sectional views showing a method for manufacturing the semiconductor memory device according to the third embodiment;

FIG. 24A and FIG. 24B are cross-sectional views showing a method for manufacturing the semiconductor memory device according to the third embodiment;

FIG. 25A and FIG. 25B are cross-sectional views showing a method for manufacturing the semiconductor memory device according to the third embodiment;

FIG. 26 is a cross-sectional view showing a semiconductor memory device according to a fourth embodiment;

FIG. 27A and FIG. 27B are cross-sectional views showing a method for manufacturing the semiconductor memory device according to the fourth embodiment;

FIG. 28A and FIG. 28B are cross-sectional views showing a method for manufacturing the semiconductor memory device according to the fourth embodiment;

FIG. 29A and FIG. 29B are cross-sectional views showing a method for manufacturing the semiconductor memory device according to the fourth embodiment;

FIG. 30A and FIG. 30B are cross-sectional views showing a method for manufacturing the semiconductor memory device according to the fourth embodiment;

FIG. 31A and FIG. 31B are cross-sectional views showing a method for manufacturing the semiconductor memory device according to the fourth embodiment; and

FIG. 32 is a cross-sectional view showing a method for manufacturing the semiconductor memory device according to the fourth embodiment.

### DETAILED DESCRIPTION

According to an embodiment, a method for manufacturing a semiconductor memory device includes forming a stacked body on a substrate by alternately stacking a first insulating layer and a first layer, forming a plurality of first through-holes in the stacked body, the plurality of first through-holes extending in a stacking direction of the first insulating layer and the first layer, forming main body portions inside the plurality of first through-holes, each of the main body portions including a charge storage film and a semiconductor portion, forming a second insulating layer on the stacked body and the plurality of main body portions, forming a second layer on the second insulating layer, forming a third layer on the second layer, forming a plurality of second through-holes in the second layer and the third layer, the plurality of second through-holes extending in the stacking direction, piercing the second layer and the third layer, reaching the second insulating layer, and being positioned directly above the plurality of main body portions, removing a portion of the second layer to widen diameters of a portion of the plurality of second through-holes, forming a fourth layer after forming a third insulating layer, the third insulating layer being formed on the second layer and the third layer exposed inside the plurality of second through-holes, the fourth layer being used to form a gate material and being formed inside the portion where the diameters of the plurality of second through-holes are widened, forming a first insulating film on a side surface of the fourth layer inside the plurality of second through-holes, after the forming of the first insulating film, removing a portion of the second insulating layer to expose upper surfaces of the plurality of main body portions at bottom portions of the plurality of second through-holes, forming a plurality of connection portions on the plurality of main body portions by filling a semiconductor material into the plurality of second through-holes, and after the forming of the plurality of connection portions, removing the third layer and a remaining portion of the second layer, the remaining portion of the second layer not being removed in the removing of the portion of the second layer.

Embodiments of the invention will now be described with reference to the drawings.

The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

In the drawings and the specification of the application, components similar to those described thereinabove are marked with like reference numerals, and a detailed description is omitted as appropriate.

### First Embodiment

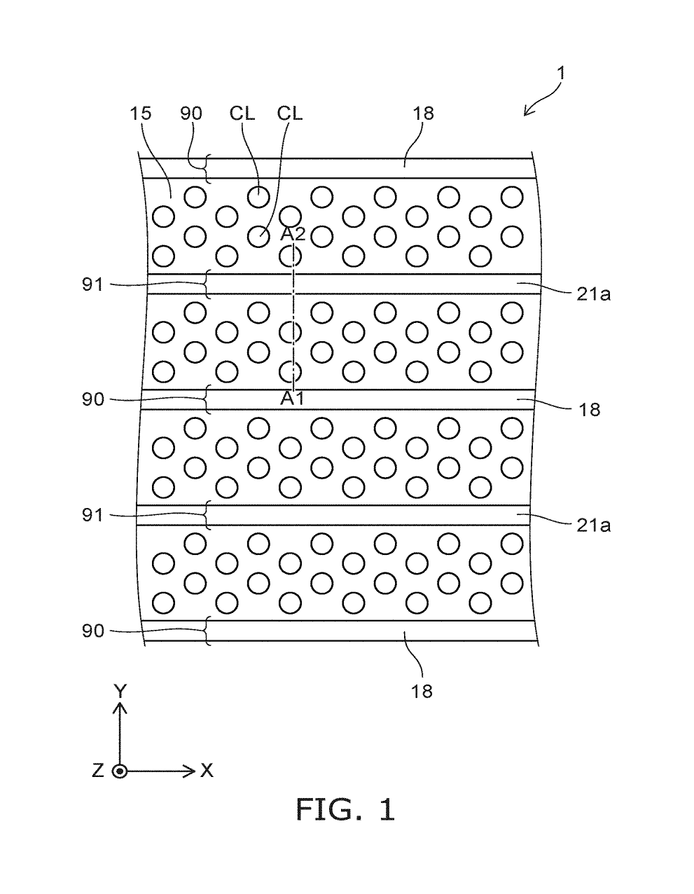

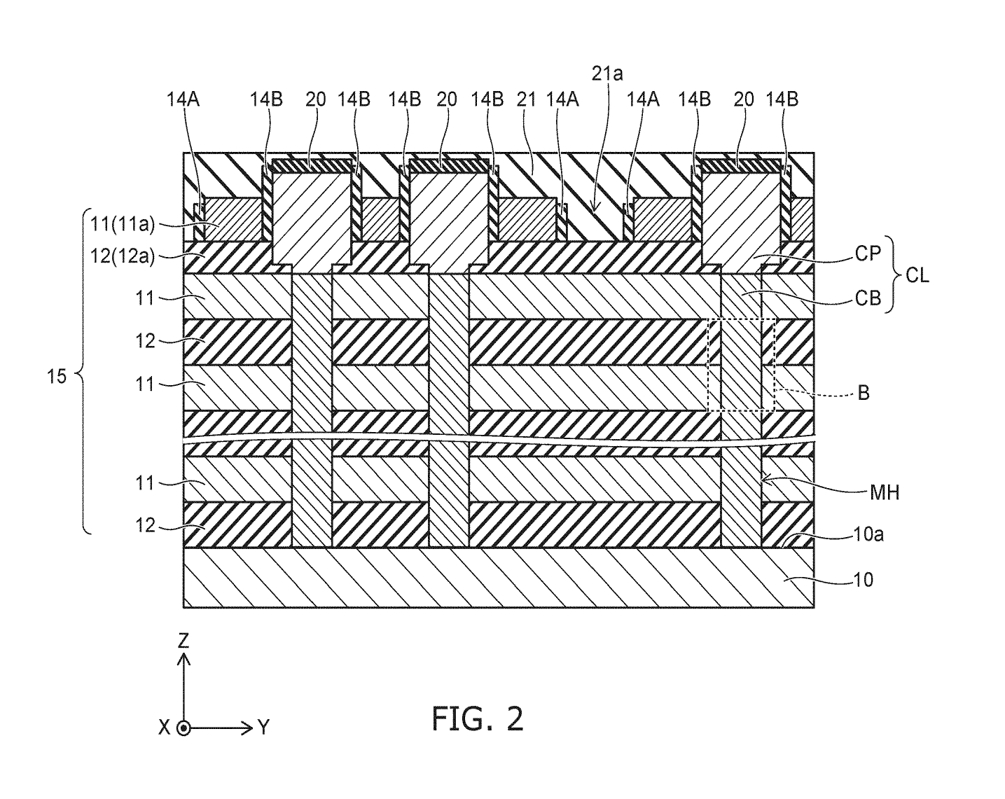

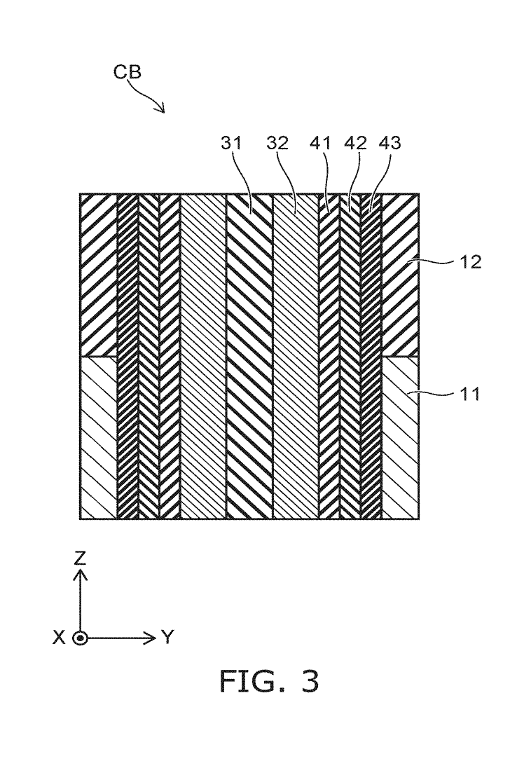

FIG. 1 is a plan view showing a semiconductor memory device 1. FIG. 2 is a cross-sectional view of line A1-A2 of FIG. 1. FIG. 3 is an enlarged view of region B of FIG. 2.

Bit lines BL are not illustrated in FIG. 2.

As shown in FIG. 1 and FIG. 2, a substrate 10 is provided in the semiconductor memory device 1. The substrate 10 is a semiconductor substrate and includes silicon (Si) such as single-crystal silicon, etc.

In the specification, two mutually-orthogonal directions parallel to an upper surface 10a of the substrate 10 are taken as an X-direction and a Y-direction. A direction that is orthogonal to both the X-direction and the Y-direction is taken as a Z-direction.

A stacked body 15, columnar portions CL, insulating portions 21a, and insulating members 18 are further provided in the semiconductor memory device 1. The stacked body 15 is provided on the substrate 10. The stacked body 15 is not limited to the substrate 10 as a foundation; and a circuit portion in which circuit elements and interconnect layers are formed may be formed as a foundation on the substrate 10. The stacked body 15 includes multiple electrode layers 11 and multiple insulating layers 12. The number of stacks of the electrode layers 11 in the stacked body 15 is arbitrary.

For example, the multiple electrode layers 11 of the stacked body 15 include a source-side select gate, a drain-side select gate, and word lines. For example, among the multiple electrode layers 11 of the stacked body 15, the source-side select gate corresponds to the electrode layer 11 of the lowermost layer; the drain-side select gate corresponds to the electrode layer 11 (11a) of the uppermost layer; and the word lines correspond to the electrode layers 11 other than the electrode layer 11 of the lowermost layer and the electrode layer 11 (11a) of the uppermost layer.

The electrode layers 11 include a conductive material and include, for example, a metal such as tungsten (W), etc. The electrode layers 11 may include a compound of a metal and silicon, e.g., a metal silicide. Among the multiple electrode layers 11, the electrode layer 11 (11a) of the uppermost layer may include a material that is different from the electrode layers 11 other than the electrode layer 11 of the uppermost layer. For example, the electrode layer 11 of the uppermost layer may include a metal silicide; and the electrode layers 11 other than the electrode layer 11 of the uppermost layer may include a metal.

For example, a main body portion that includes a metal and/or a metal silicide may be provided in the electrode layer 11; and a barrier metal layer that includes titanium nitride (TiN) and covers the surface of the main body portion may be provided in the electrode layer 11.

The insulating layers 12 are provided on the substrate 10 and between the electrode layers 11. The insulating layers 12 include, for example, silicon oxide (SiO). Among the multiple insulating layers 12, the insulating layer 12 (12a) of the uppermost layer is positioned between the electrode layer 11 (11a) of the uppermost layer and the second electrode layer 11 from the top of the multiple electrode layers 11. An insulating film 14A is provided on the two side surfaces of the electrode layer 11 (11a) of the uppermost layer of the stacked body 15. The insulating film 14A includes, for example, silicon oxide.

Memory holes MH (through-holes) are provided in the stacked body 15. The columnar portions CL are positioned inside the memory holes MH. As shown in FIG. 1, the columnar portions CL are multiply provided and arranged in, for example, a lattice configuration in the X-direction and the Y-direction.

The columnar portion CL includes a main body portion CB and a connection portion CP. As shown in FIG. 3, the main body portion CB includes a core insulating film 31, a channel 32, a tunneling insulating film 41, a charge storage film 42, and a blocking insulating film 43.

The core insulating film 31 includes, for example, silicon oxide. For example, the core insulating film 31 extends in the Z-direction in a columnar configuration. The core insulating film 31 may not be included in the main body portion CB.

The channel 32 is provided at the periphery of the core insulating film 31. The channel 32 is a semiconductor portion and includes, for example, silicon. The channel 32 includes, for example, polysilicon made of amorphous silicon that is crystallized. The channel 32 extends in the Z-direction in a tubular configuration. The lower end of the channel 32 contacts the substrate 10.

The tunneling insulating film 41 is provided at the periphery of the channel 32. The tunneling insulating film 41 includes, for example, silicon oxide. The tunneling insulating film 41 is a potential barrier between the charge storage film 42 and the channel 32. When programming, information is programmed by electrons tunneling through the tunneling insulating film 41 from the channel 32 into the charge storage film 42. On the other hand, when erasing, the information that is stored is erased by holes tunneling through the tunneling insulating film 41 from the channel 32 into the charge storage film 42 and canceling the charge of the electrons.

The charge storage film 42 is provided at the periphery of the tunneling insulating film 41. The charge storage film 42 includes, for example, silicon nitride (SiN).

A memory cell that includes the charge storage film 42 is formed at each crossing portion between the channel 32 and the electrode layers 11 (the word lines). The charge storage film 42 has trap sites that trap charge inside a film. The threshold voltage of the memory cell changes according to the existence or absence of the charge trapped in the trap sites and the amount of the trapped charge. Thereby, the memory cell stores information.

The blocking insulating film 43 is provided at the periphery of the charge storage film 42. The blocking insulating film 43 includes, for example, silicon oxide. The blocking insulating film 43 may include multiple films, e.g., a stacked film of a silicon oxide film and an aluminum oxide film. For example, the blocking insulating film 43 protects the charge storage film 42 from the etching when forming the electrode layer 11. Also, the blocking insulating film 43 suppresses the discharge of the charge stored in the charge storage film 42 into the electrode layer 11 and back-tunneling of the electrons from the electrode layer 11 into the columnar portion CL.

The connection portion CP is provided on the main body portion CB. The connection portion CP is positioned inside a portion of the stacked body 15 (the insulating layer 12a of the uppermost layer of the multiple insulating layers 12 and the electrode layer 11a of the uppermost layer of the multiple electrode layers 11) and inside an inter-layer insulating layer 21. For example, the thickness in the Y-direction (the X-direction) of the connection portion CP becomes thicker in stages in the Z-direction. For example, the connection portion CP includes multiple portions having different thicknesses in the Y-direction (the X-direction) inside the insulating layer 12a. The connection portion CP includes a semiconductor material, e.g., amorphous silicon. The lower end of the connection portion CP contacts the channel 32 of the main body portion CB. Thereby, the connection portion CP is electrically connected to the channel 32.

An insulating film 14B is provided at the periphery of the connection portion CP. In FIG. 2, the insulating film 14B is positioned between the connection portion CP of the columnar portion CL and the electrode layer 11a of the stacked body 15 in the Y-direction. The insulating film 14B includes the same material as the insulating film 14A, e.g., silicon oxide.

An insulating film 20 is provided on the columnar portion CL (the connection portion CP). The insulating film 14B and the insulating film 20 cover the surface of a portion of the connection portion CP.

The inter-layer insulating layer 21 is provided on the stacked body 15 (the electrode layer 11a) and on the insulating film 14A, the insulating film 14B, and the insulating film 20. The inter-layer insulating layer 21 includes, for example, silicon oxide.

As shown in FIG. 1, trenches 91 that extend in the X-direction are provided in the stacked body 15. The insulating portions 21a are positioned inside the trenches 91. As shown in FIG. 2, the insulating portion 21a is a portion of the inter-layer insulating layer 21. The insulating portion 21a is a portion that is disposed inside the upper portion of the stacked body 15 and divides the electrode layer 11 of one or more layers from the top into two each. In the example of FIG. 2, the electrode layer 11a is divided in the Y-direction by the insulating portion 21a. For example, the drain-side select gate is divided in the Y-direction by the insulating portion 21a. The insulating portion 21a includes the same material as the inter-layer insulating layer 21, e.g., silicon oxide.

As shown in FIG. 1, slits 90 that extend in the X-direction and the Z-direction are provided in the stacked body 15. The insulating members 18 are positioned inside the slits 90. The insulating members 18 are multiply provided and extend through the stacked body 15 in the X-direction and the Z-direction. The multiple electrode layers 11 that are stacked in the Z-direction are subdivided in the Y-direction as blocks by the multiple insulating members 18 extending in the X-direction and the Z-direction. That is, each of the blocks corresponds to a portion between the mutually-adjacent insulating members 18 in which the electrode layers 11 between the insulating members 18 form word lines as control gates.

A member that includes a conductive body in a portion of the member may be positioned inside the slit 90 instead of the insulating member 18. For example, an interconnect portion may be formed inside the slit 90 so that the lower end of the interconnect portion contacts the substrate 10 and the upper end of the interconnect portion is connected to a source line.

Although the insulating members 18 are arranged in the Y-direction alternately with the insulating portions 21a in the example shown in FIG. 1, the arrangement of the insulating portions 21a and the insulating members 18 is arbitrary. The insulating portions 21a may be provided also above the insulating members 18 subdividing the electrode layers 11 used as the word lines every block; and the insulating portions 21a may be formed at a pitch in the Y-direction that is 1/n of that of the insulating members 18 (n being an integer of 2 or more) and arranged so that the electrode layers 11 other than the electrode layer 11 (11a) of the uppermost layer are subdivided in the Y-direction by the insulating members 18 and so that the electrode layer 11a of the uppermost layer is subdivided in the Y-direction by only the insulating portions 21a.

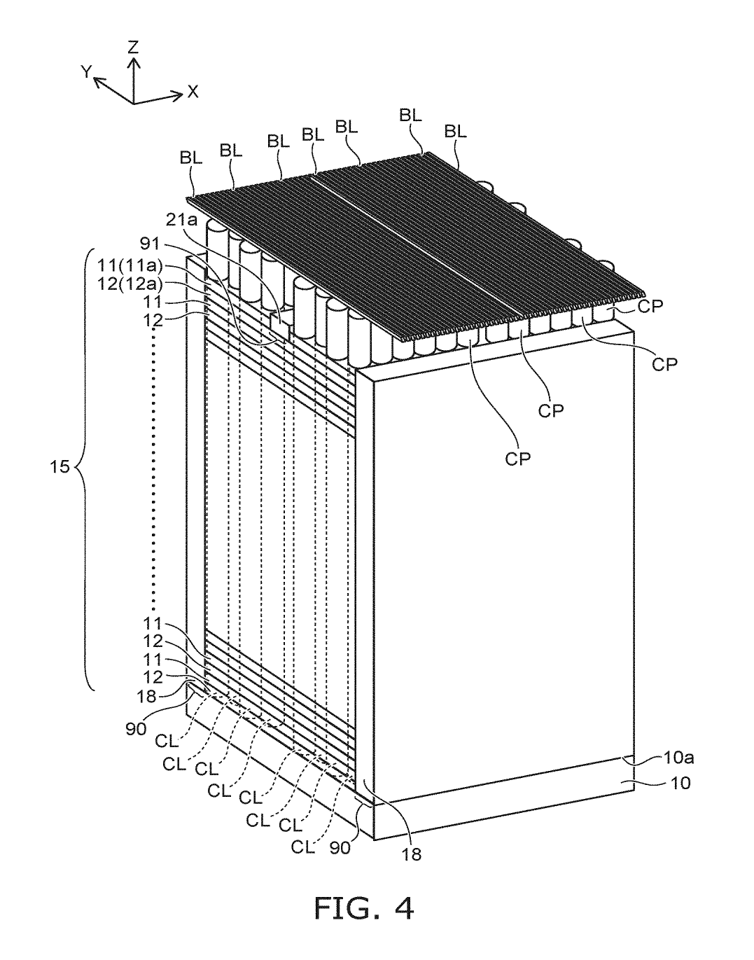

FIG. 4 is a perspective view showing a portion of the semiconductor memory device 1.

FIG. 4 is a perspective view schematically showing a portion of the region shown in FIG. 1 which is the stacked body 15, the columnar portions CL, and the insulating portions 21a provided between the insulating members 18 adjacent to each other in the Y-direction.

As shown in FIG. 4, the bit lines BL are provided on the columnar portions CL (on the connection portions CP). The columnar portions CL are connected to the bit lines BL. For example, the bit line BL extends in the Y-direction over the stacked bodies 15 of multiple blocks and is connected to one columnar portion CL of each unit of the stacked bodies 15 selectable by each drain-side select gate (electrode layer 11a).

In the semiconductor memory device 1, many memory cells that each includes the charge storage film 42 are arranged in a three-dimensional lattice configuration along the X-direction, the Y-direction, and the Z-direction; and data can be stored in each of the memory cells.

A method for manufacturing the semiconductor memory device according to the embodiment will now be described.

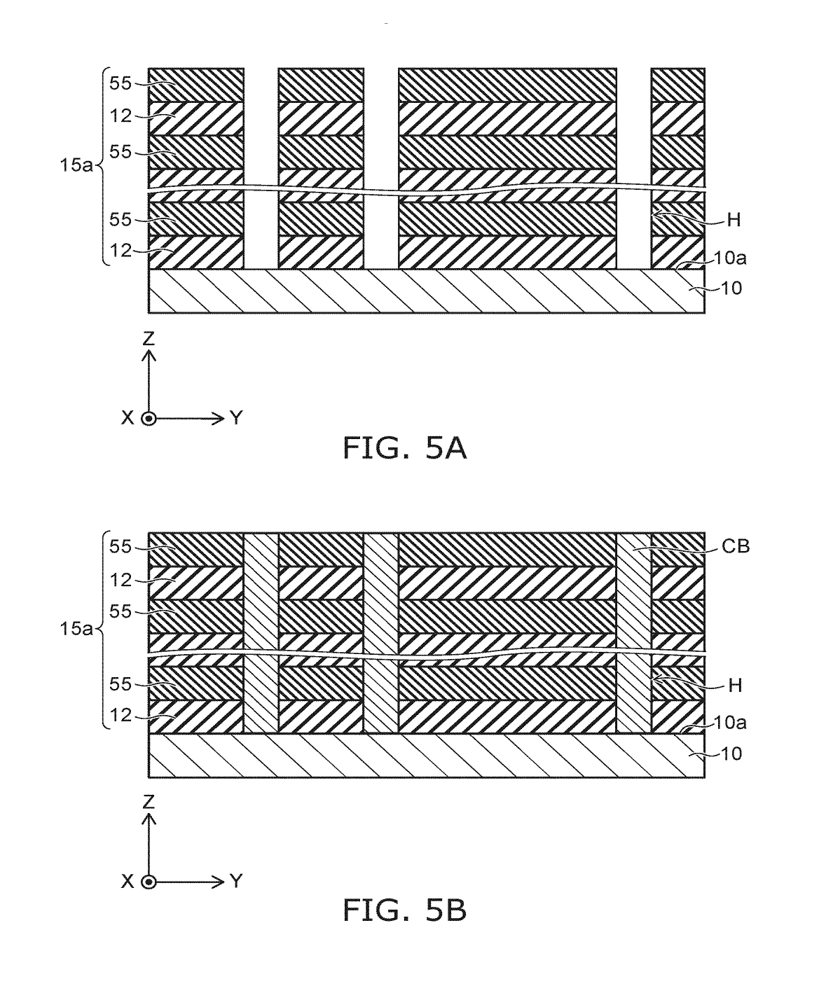

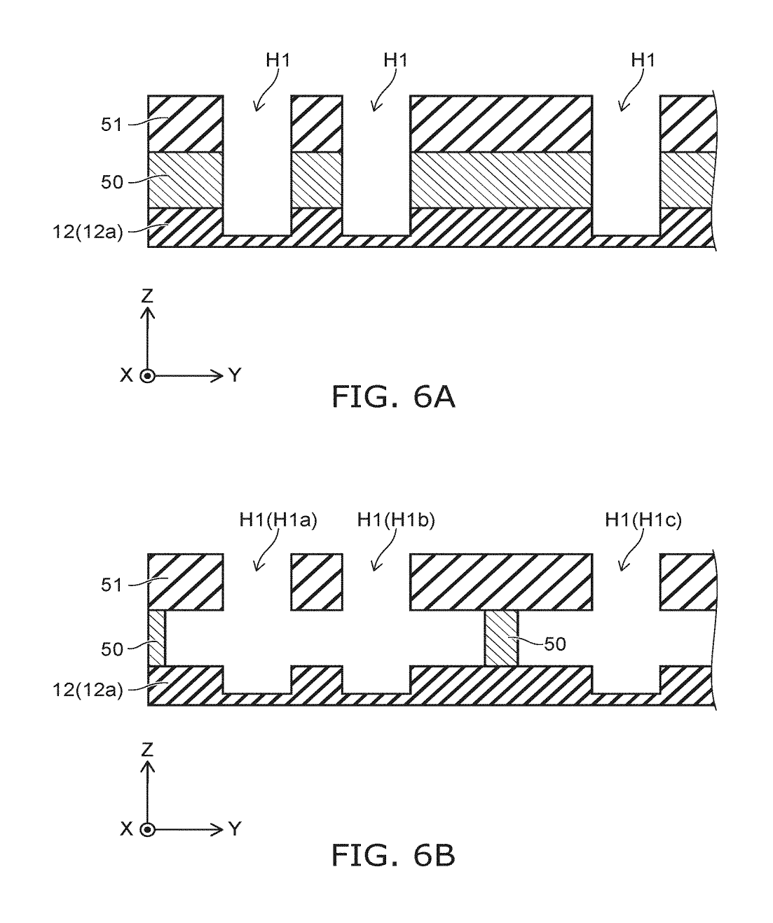

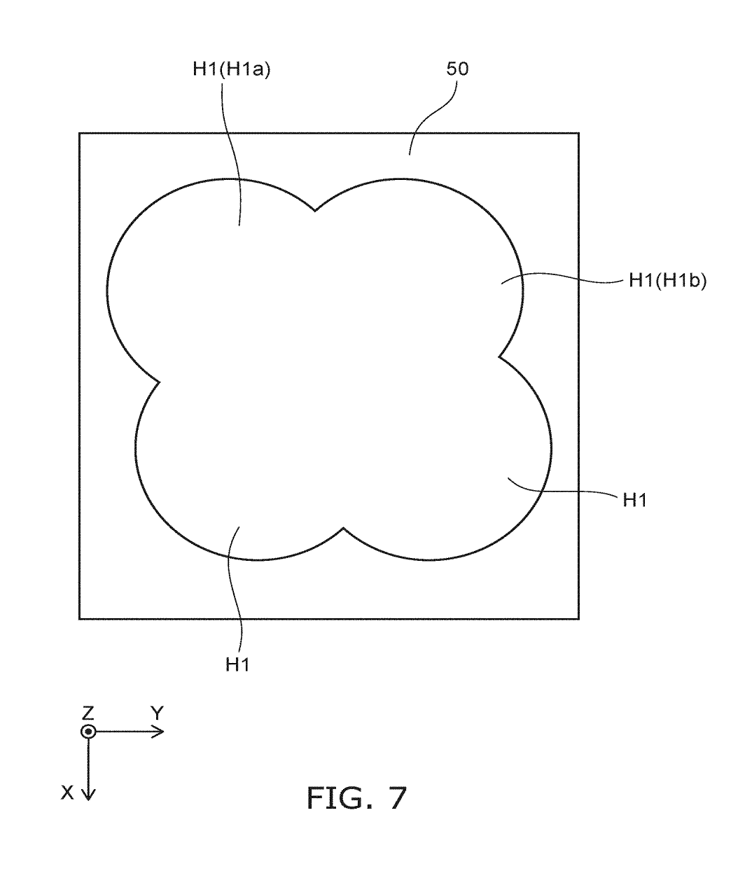

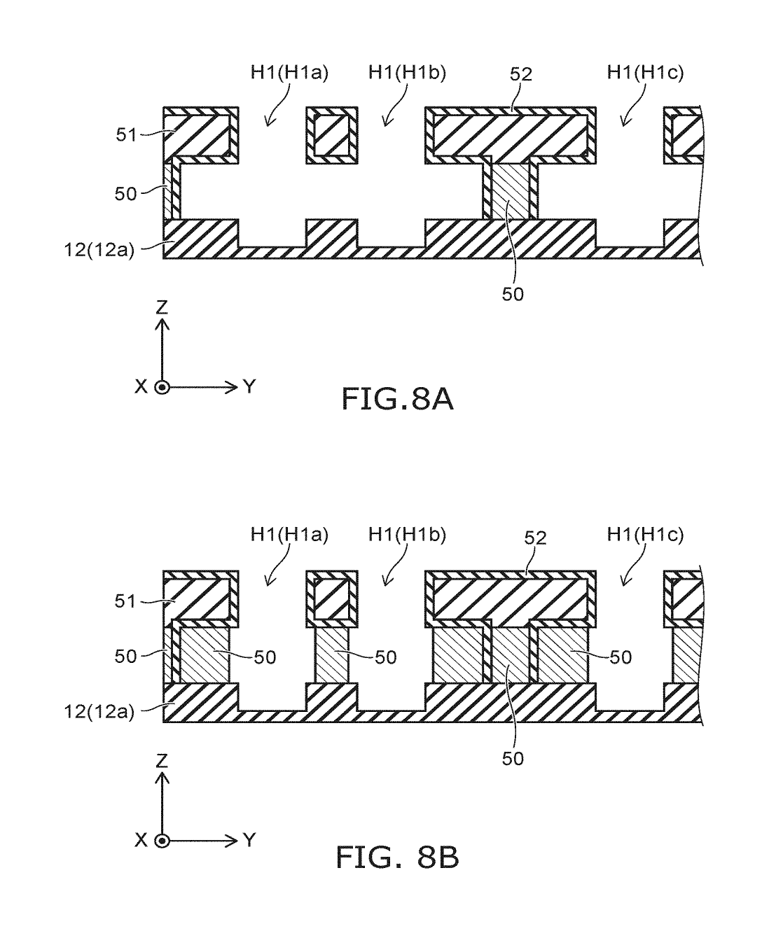

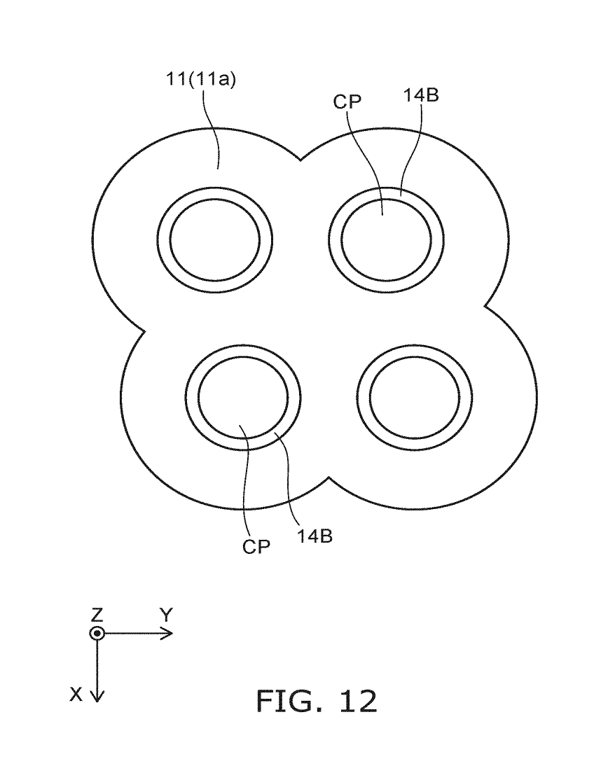

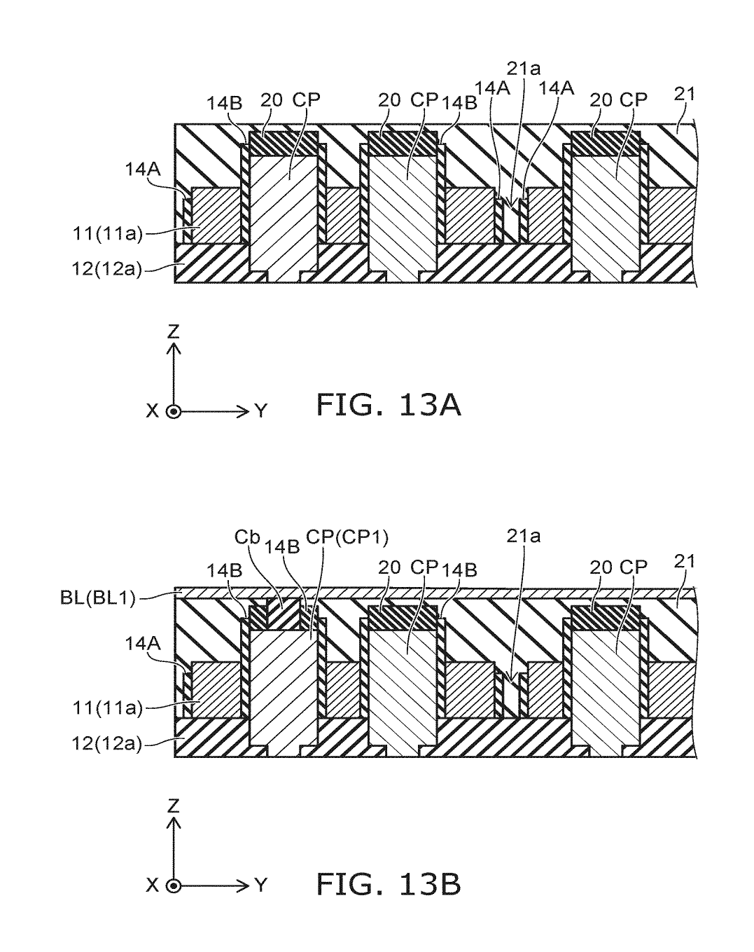

FIG. 5A and FIG. 5B, FIG. 6A and FIG. 6B, FIG. 7, FIG. 8A and FIG. 8B to FIG. 11A and FIG. 11B, FIG. 12, FIG. 13A, and FIG. 13B are drawings showing the method for manufacturing the semiconductor memory device 1.

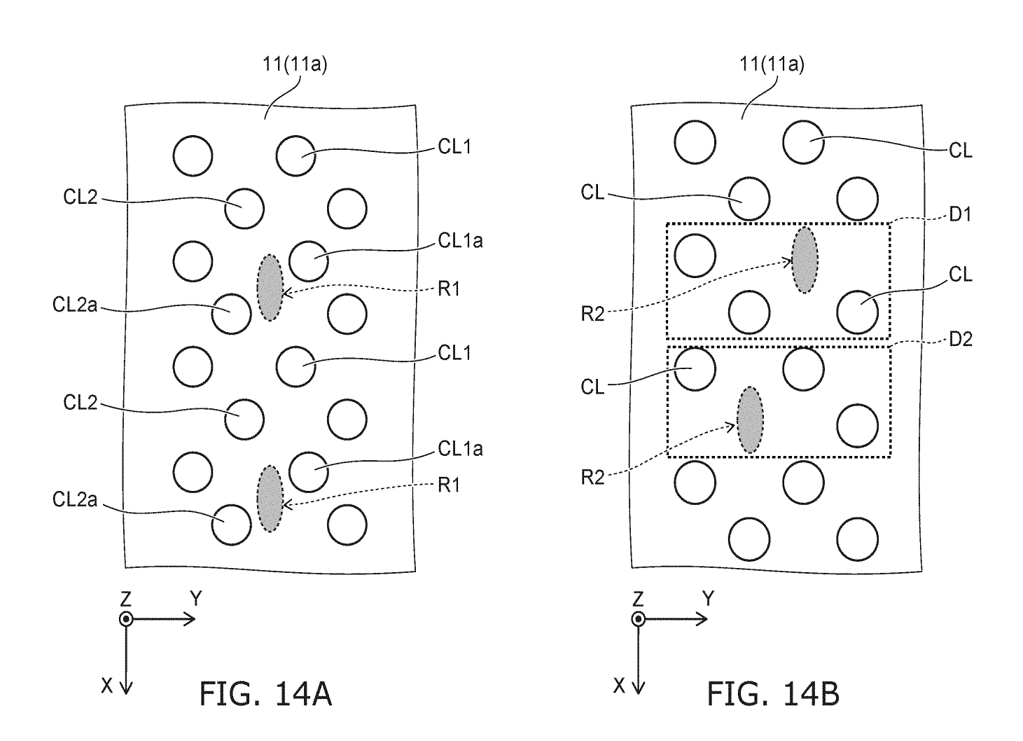

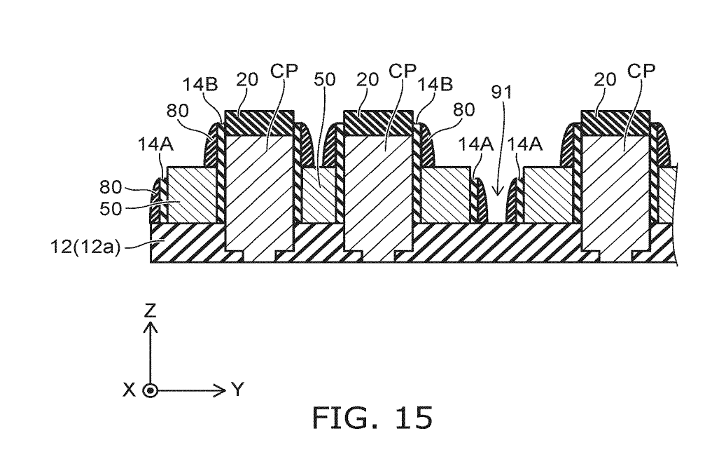

FIG. 14A, FIG. 14B, and FIG. 15 are drawings showing a method for manufacturing the semiconductor memory device 1 of a modification.

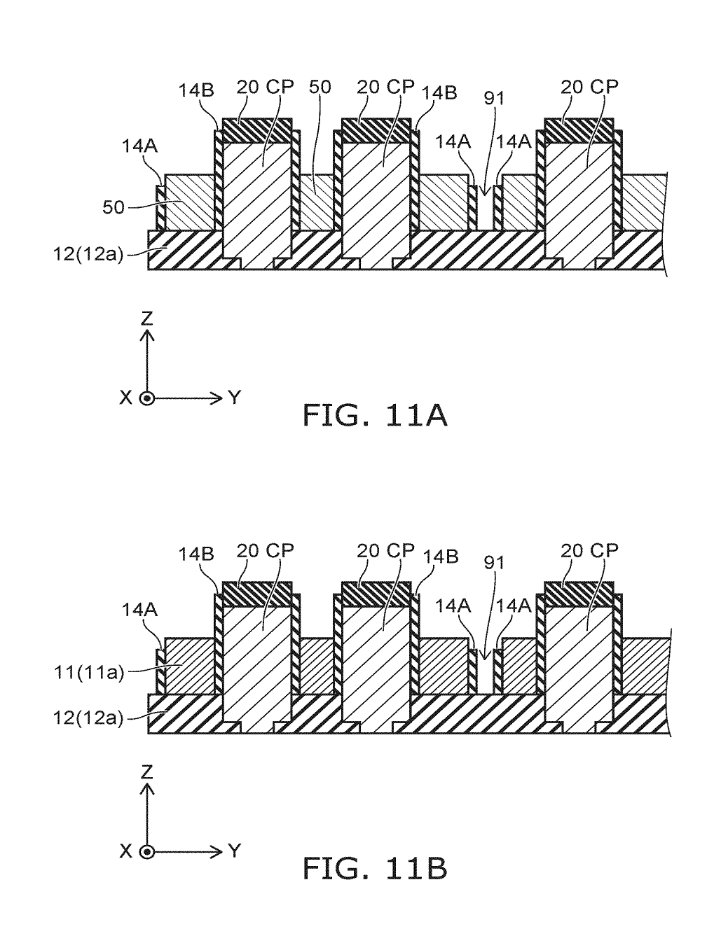

The region shown in FIG. 5A and FIG. 5B is a portion of the region shown in FIG. 2 and corresponds to a portion below the insulating layer 12a. The region shown in FIG. 6A and FIG. 6B, FIG. 8A and FIG. 8B to FIG. 11A and FIG. 11B, FIG. 13A, and FIG. 13B is a portion of the region shown in FIG. 2 and corresponds to a portion of the insulating layer 12a and above. FIG. 7 and FIG. 12 are plan views when viewed from the Z-direction respectively of the processes of FIG. 6B and FIG. 11B.

The region shown in FIG. 14A and FIG. 14B shows a portion of the region shown in FIG. 1 and shows arrangements of the columnar portions CL between the insulating portion 21a and the insulating member 18. Although not illustrated in FIG. 14A and FIG. 14B, the insulating portion 21a and the insulating member 18 are positioned on the two Y-direction sides; the insulating portion 21a is positioned on the Y-direction side; and the insulating member 18 is positioned on the −Y direction side.

The region shown in FIG. 15 is a portion of the region shown in FIG. 2 and corresponds to a portion of the insulating layer 12a and above.

The formation processes of the portion below the insulating layer 12a and the main body portions CB of the columnar portions CL of the semiconductor memory device 1 will now be described using FIG. 5A and FIG. 5B; then, the formation processes of the portion of the insulating layer 12a and above and the connection portions CP of the columnar portions CL of the semiconductor memory device 1 will be described using FIG. 6A and FIG. 6B, FIG. 7, FIG. 8A and FIG. 8B to FIG. 11A and FIG. 11B, FIG. 12, FIG. 13A, and FIG. 13B.

First, the formation processes of the portion below the insulating layer 12a and the main body portions CB of the columnar portions CL of the semiconductor memory device 1 will be described using FIG. 5A and FIG. 5B.

As shown in FIG. 5A by, for example, CVD (Chemical Vapor Deposition), a stacked body 15a is formed on the substrate 10 by alternately stacking the insulating layers 12 including silicon oxide and sacrificial layers 55 including silicon nitride along the Z-direction. Continuing, through-holes H are formed in the stacked body by etching such as RIE (Reactive Ion Etching), etc.

Then, as shown in FIG. 5B by, for example, CVD, the blocking insulating film 43 is formed by depositing silicon oxide on the inner wall surfaces of the through-holes H; the charge storage film 42 is formed by depositing silicon nitride on the blocking insulating film 43; and the tunneling insulating film 41 is formed by depositing silicon oxide on the charge storage film 42 (referring to FIG. 3). Continuing, the channel 32 is formed by depositing silicon; and the core insulating film 31 is formed by depositing silicon oxide (referring to FIG. 3). Thereby, the main body portions CB of the columnar portions CL are formed inside the through-holes H.

The formation processes of the portion of the insulating layer 12a and above and the connection portions CP of the columnar portions CL of the semiconductor memory device 1 will now be described using FIG. 6A and FIG. 6B, FIG. 7, FIG. 8A and FIG. 8B to FIG. 11A and FIG. 11B, FIG. 12, FIG. 13A, and FIG. 13B.

In the processes of FIG. 5A and FIG. 5B, the portion below the insulating layer 12a and the main body portions CB of the columnar portions CL are formed; subsequently, as shown in FIG. 6A by, for example, CVD, the insulating layer 12a is formed on the stacked body 15a and the main body portions CB of the columnar portions CL; and a layer 50 is formed on the insulating layer 12a. For example, the insulating layer 12a is formed of silicon oxide; and the layer 50 is formed of amorphous silicon. Subsequently, a layer 51 is formed on the layer 50. The layer 51 is formed of silicon nitride.

Continuing, holes H1 (through-holes) are formed in the layer 50 and the layer 51 by etching such as RIE, etc. The holes H1 extend in the Z-direction, pierce the layer 50 and the layer 51, and reach the insulating layer 12a. The holes H1 are positioned directly above the main body portions CB of the columnar portions CL. Although the holes H1 are formed to further reach the interior of a region on a relatively lower side of the insulating layer 12a after the holes H1 pierce the layer 50 in the example of FIG. 6A, the etching of the holes H1 may be stopped at the upper surface of the insulating layer 12a; and the holes H1 may not be formed into the insulating layer 12a.

Then, as shown in FIG. 6B, the layer 50 is selectively removed by performing wet etching via the holes H1 (H1a, H1b, and H1c). A portion of the holes H1 (H1a, H1b, and H1c) is widened in the Y-direction by the layer 50 being selectively removed; and a recess is formed in the portion where the layer 50 is removed on the insulating layer 12a. For example, the conditions of the etching (e.g., the processing time) are set so that the two holes H1a and H1b communicate in the Y-direction. On the other hand, the two holes H1b and H1c do not communicate in the Y-direction. Thereby, a portion of the layer 50 remains without being removed.

In FIG. 6B, the two holes H1a and H1b that are arranged along the Y-direction are shown as communicating in the Y-direction. In the case where the multiple holes H1 are formed so that the columnar portions CL are arranged as in FIG. 1, the mutually-adjacent holes H1 that are arranged along the X-direction communicate with each other in the X-direction.

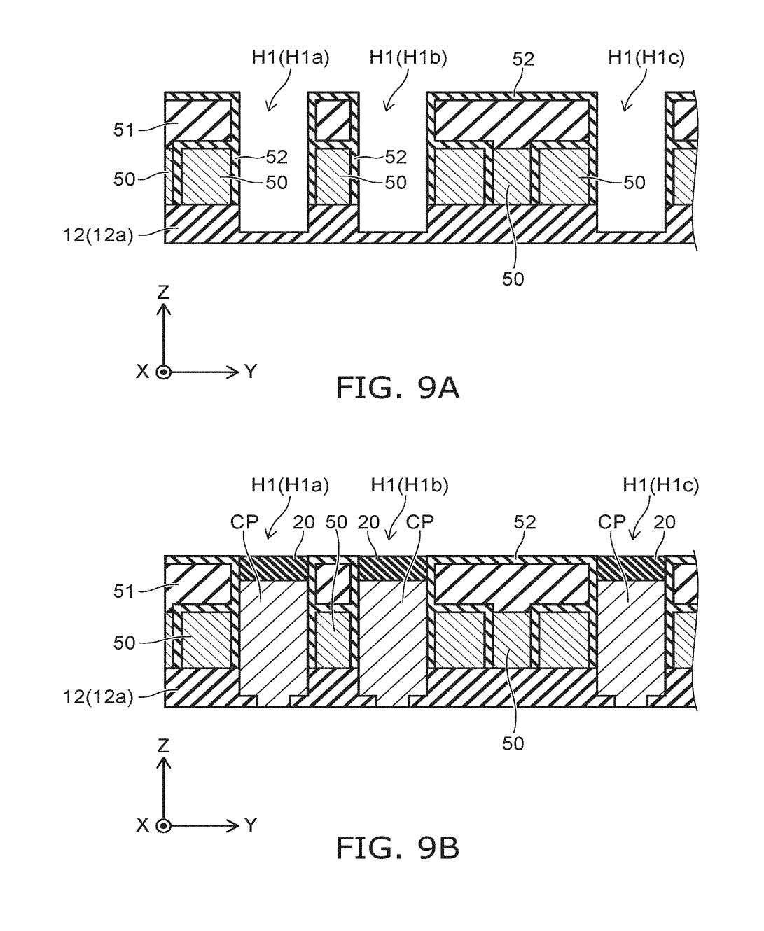

That is, in the case where the multiple holes H1 are formed so that the multiple columnar portions CL are arranged in a lattice configuration in the X-direction and the Y-direction between the insulating portion 21a and the insulating member as in FIG. 1, the multiple holes H1 are caused to communicate in a direction (e.g., the X-direction and/or the Y-direction) orthogonal to the Z-direction by widening the diameters of the multiple holes H1. In such a case, for example, as shown in FIG. 7, the etching progresses to form multiple substantially circles when viewed from the Z-direction. FIG. 7 shows a formation example of four holes H1 corresponding to four columnar portions CL in the case where the multiple columnar portions CL are arranged in a lattice configuration in the X-direction and the Y-direction such as that of FIG. 1. For example, the two holes H1a and H1b of FIG. 7 correspond to the two holes H1a and H1b communicating in the Y-direction in FIG. 6B. Thereby, the connection portions CP of the multiple columnar portions CL formed in the process of FIG. 9B described below are positioned inside the electrode layer 11 (11a) formed in the process of FIG. 11B described below.

Then, as shown in FIG. 8A, an insulating film 52 is formed on the layer 51, the inner wall surface of the hole H1c, and the inner wall surfaces of the two holes H1a and H1b communicating in the Y-direction by, for example, ALD (Atomic Layer Deposition). The insulating film 52 is formed on the layers 50 and 51 inside the two holes H1a and H1b communicating in the Y-direction. Also, the insulating film 52 is formed on the layers 50 and 51 inside the hole H1c. The insulating film 52 is formed of, for example, silicon oxide.

Continuing as shown in FIG. 8B by, for example, CVD, the layer 50 is re-formed, via the holes H1 (H1a, H1b, and H1c), inside the recess on the insulating layer 12a where the layer 50 was selectively removed in the process of FIG. 6B. That is, the layer 50 is filled into the holes H1 (H1a, H1b, and H1c) that were widened in the X-direction and the Y-direction in the process of FIG. 6B.

Then, as shown in FIG. 9A, the insulating film 52 is formed by, for example, performing thermal oxidation of the surface of the layer 50 exposed inside the holes H1 (H1a, H1b, and H1c). The insulating film 52 is formed on the layer 50 filled in the process of FIG. 8B.

Continuing as shown in FIG. 9B, a portion of the insulating layer 12a is removed from the bottom surfaces of the holes H1 (H1a, H1b, and H1c) by etching such as RIE, etc. Thereby, the holes H1 (H1a, H1b, and H1c) pierce the insulating layer 12a and reach the main body portions CB of the columnar portions CL (referring to FIG. 5B). Continuing, the connection portions CP are formed by depositing amorphous silicon inside the holes H1 (H1a, H1b, and H1c) by, for example, CVD. Subsequently, the insulating film 20 is formed on the connection portions CP inside the holes H1 (H1a, H1b, and H1c). The insulating film 20 is formed of, for example, silicon oxide.

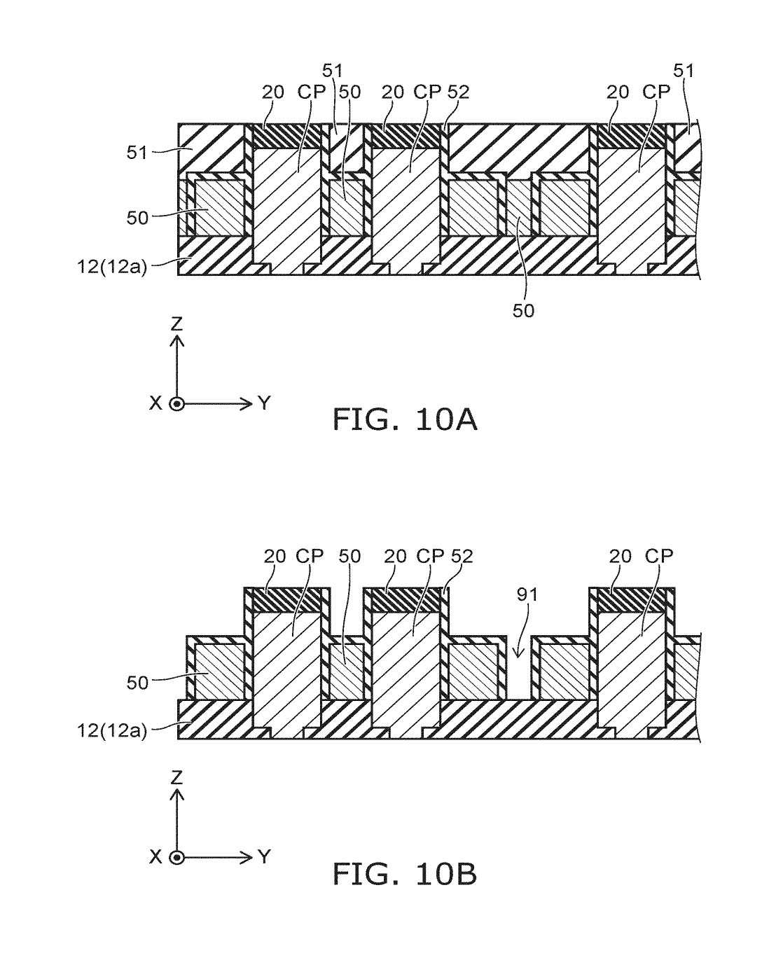

Continuing as shown in FIG. 10A, the insulating film 52 that is on the layer 51 is removed by etching such as RIE, etc. A portion of the insulating film 20 also is removed by the etch-back.

Then, as shown in FIG. 10B, the layers 50 and 51 that are positioned on the insulating film 52 are removed by, for example, wet etching. The layers 50 and 51 that are positioned on the insulating film 52 are selectively removed due to the etching selectivity between the insulating film 52 (the silicon oxide film) and the layer 50 (the silicon layer) and between the insulating film 52 (the silicon oxide film) and the layer 51 (the silicon nitride layer). The layer 50 that is removed in the process of FIG. 10B corresponds to the portion (the remaining portion) remaining without being removed in the process of FIG. 6B. The layer 50 is exposed by the removal of the layer 51; and the trench 91 is formed by removing the exposed layer 50. The trench 91 extends in the X-direction and is formed to divide the layer 50 in the Y-direction.

Continuing as shown in FIG. 11A, the insulating film 52 that is positioned on the layer 50 is removed by etching such as RIE, etc. The upper surface of the layer 50 is exposed by removing the insulating film 52. A portion of the insulating film 52 positioned at the periphery of the insulating film 20 and on the side surface of the layer 50 also is removed. Thereby, the insulating films 14A and 14B are formed. The insulating films 14A are positioned on the two Y-direction side surfaces of the layer 50. The insulating film 14B is positioned between the connection portion CP and the layer 50 in the Y-direction.

Then, as shown in FIG. 11B, a metal such as tungsten or the like is formed on the exposed upper surface of the layer 50; subsequently, a metal silicide is formed by causing the metal to react with the silicon of the layer 50 by performing heat treatment. Thereby, the electrode layer 11 (11a) is formed. Continuing, after the formation of the metal silicide, the metal that did not react with the silicon of the layer 50 is removed using a chemical liquid.

As described above, in the processes of FIG. 6B and FIG. 7, the etching progresses to form multiple substantially circles when viewed from the Z-direction; in the process of FIG. 8B, the layer 50 is filled into the holes H1 (H1a, H1b, and H1c) having the widened diameters; subsequently, in the process of FIG. 11B, the electrode layer 11 (11a) is formed on the exposed layer 50 by performing heat treatment. By these processes as shown in FIG. 12, the connection portions CP of the multiple columnar portions CL are positioned inside the electrode layer 11 (11a). The outer edge of the electrode layer 11 (11a) has a configuration in which multiple circular arcs are combined at the two ends in the X-direction and the Y-direction when viewed from the Z-direction. FIG. 12 shows the configuration of the electrode layer 11 (11a) when viewed from the Z-direction in the case where four columnar portions CL respectively including the connection portions CP are formed. In the case where many of these columnar portions CL are arranged repeatedly in the X-direction as shown in FIG. 1, the electrode layer 11 (11a) that extends in the X-direction and is used to form the drain-side select gate has a configuration at the two side surfaces adjacent to the trenches 91 in the Y-direction in which multiple circular arcs are combined when viewed from the Z-direction.

Then, as shown in FIG. 13A, the inter-layer insulating layer 21 is formed to cover the electrode layer 11 (11a) and the columnar portions CL by, for example, CVD. The inter-layer insulating layer 21 is formed of, for example, silicon oxide. The inter-layer insulating layer 21 is formed also inside the trench 91 as the insulating portion 21a.

Continuing, the slits 90 that extend in the X-direction and the Z-direction (referring to FIG. 1 and FIG. 4) are formed in the stacked body 15a (referring to FIG. 5A and FIG. 5B), the insulating layer 12a, and the inter-layer insulating layer 21; and the sacrificial layers 55 of the stacked body 15a formed in the portion below the insulating layer 12a are removed by etching via the slits 90. Gaps are formed by removing the sacrificial layers 55 via the slits 90; and the interiors of the gaps are filled by depositing a metal such as tungsten, etc., via the slits 90. Thereby, the sacrificial layers 55 that are formed in the portion below the insulating layer 12a are replaced with the electrode layers 11; and the stacked body 15 that includes the multiple electrode layers 11 and the multiple insulating layers 12 (referring to FIG. 2) is formed. Before the process of FIG. 6A, the slits 90 that extend in the X-direction and the Z-direction may be formed in the stacked body 15a and the sacrificial layers 55 may be replaced with the electrode layers 11 via the slits 90.

Subsequently, as shown in FIG. 13B, the bit lines BL are formed on the connection portions CP. Although multiple bit lines BL such as those shown in FIG. 4 are formed above the stacked body 15, in the case where a bit line BL1 is formed directly above a connection portion CP1 as shown in FIG. 13B, for example, a hole is formed by removing a portion of the inter-layer insulating layer 21 and a portion of the insulating film 20; a connection portion Cb is formed by filling a conductive material into the hole; and subsequently, the bit line BL1 that is connected to the connection portion Cb is formed.

Thus, the semiconductor memory device 1 according to the embodiment is manufactured.

Here, for example, as shown in FIG. 1, the columnar portions CL are arranged in a lattice configuration in the X-direction and the Y-direction. In such an arrangement of the columnar portions CL, the volume of the gaps is large due to the two holes H1 communicating with each other in the Y-direction due to the wet etching in the process of FIG. 6B; and collapse of the structure body including the insulating layer 12a, the layer 50, and the layer 51 may occur due to the decrease of the strength of the structure body.

Accordingly, several columnar portions CL of the multiple columnar portions CL may be formed to be toward the outer side of the electrode layer 11a. For example, as shown in FIG. 14A, columnar portions CL1a of the multiple columnar portions CL arranged in the lattice configuration in the X-direction and the Y-direction are positioned toward the outer side to reduce the distance in the Y-direction to the insulating portion 21a (referring to FIG. 1) compared to columnar portions CL1. Also, columnar portions CL2a are positioned toward the outer side to reduce the distance in the Y-direction to the insulating member 18 compared to columnar portions CL2. Thus, by arranging the columnar portions CL1a and CL2a, compared to an arrangement of the columnar portions CL such as that of FIG. 1, the layer 50 remains easily in the process of FIG. 6B in the portions shown by regions R1; therefore, the volume of the layer 50 becomes large. That is, the portions shown by the regions R1 function as posts; therefore, the strength of the structure body including the insulating layer 12a, the layer 50, and the layer 51 increases; and the collapse of the structure body can be suppressed.

Also, to suppress the collapse of the structure body, the number of the columnar portions CL may be reduced. By reducing the number of the columnar portions CL, the number of the connection portions CP (referring to FIG. 9B) decreases; therefore, the collapse due to the decrease of the strength of the structure body including the insulating layer 12a, the layer 50, and the layer 51 due to the wet etching can be suppressed. For example, it is desirable to reduce the number of the columnar portions CL disposed on the inner side relatively distal to the insulating portion 21a or the insulating member 18 in the Y-direction compared to the other columnar portions CL. For example, as shown in regions D1 and D2 of FIG. 14B, the columnar portions CL are not positioned in the portions shown by regions R2; therefore, compared to an arrangement of the columnar portions CL such as those of FIG. 1 and FIG. 14A, the layer 50 remains easily in the process of FIG. 6B; therefore, the volume of the layer 50 becomes large. That is, the portions shown by the regions R2 function as posts; therefore, the strength of the structure body including the insulating layer 12a, the layer 50, and the layer 51 is large; and the collapse of the structure body can be suppressed further.

As shown in FIG. 15, an insulating film 80 may be formed on the side surface of the insulating film 14A and on the exposed side surface of the insulating film 14B between the processes of FIG. 11A and FIG. 11B. For example, the insulating film 80 is formed by forming an oxide film such as a silicon oxide film, etc., on the entire surface after the process of FIG. 11A and by subsequently etching a portion of the oxide film so that the oxide film remains on the side surfaces of the insulating films 14A and 14B. Thereby, the connection portions CP of the columnar portions CL are protected in the process of FIG. 11B. For example, the damage of the side surfaces of the connection portions CP in a formation process of a metal silicide such as that of FIG. 11B is suppressed.

Effects of the embodiment will now be described.

In a semiconductor memory device that has a three-dimensional structure, the contacts that are connected to the channels are formed by forming holes directly above the channels in the upper portion of the stacked body including the multiple electrode layers. Also, trenches are formed in the upper portion of the stacked body including the multiple electrode layers; and subsequently, the electrode layer (the drain-side select gate) of the upper layer is divided by filling the interiors of the trenches with an insulating material. Here, in the case where the electrode layers inside the stacked body include a metal, it is difficult to pattern the electrode layers; and the wafer is contaminated easily by metal impurities when patterning the electrode layers.

In the case where the contacts are formed by forming multiple holes in the upper portion of the stacked body, taper angles occur easily in the holes inside the stacked body due to the patterning of the electrode layer including a metal. Such holes are formed so that the thickness in the Y-direction decreases toward the lower layers (in the −Z direction); therefore, by considering the connection between the channel and the contact, the holes are formed to have prescribed widths at the upper surface. Thereby, it is difficult to reduce the distance (the distance in the Y-direction) between the mutually-adjacent contacts; and it is difficult to reduce the pitch of the memory holes. Accordingly, it is difficult to downscale the memory cell.

In the case where the electrode layer (the drain-side select gate) of the upper layer is divided by forming a trench in the upper portion of the stacked body, a taper angle occurs easily in the trench due to the patterning of the electrode layer including a metal. Such a trench is formed so that the thickness in the Y-direction decreases toward the lower layers (in the −Z direction); therefore, the breakdown voltage between mutually-adjacent electrode layers of the upper layer having the trench interposed is low.

In the semiconductor memory device 1 of the embodiment, the holes H1 that pierce the layers 50 and 51 are formed after stacking the layers 50 and 51 including silicon as shown in the processes of FIG. 6A and FIG. 6B. Also, the connection portions CP of the columnar portions CL are formed inside the holes H1 as shown in the process of FIG. 9B; and the electrode layer 11 (11a) is formed by processing the layer 50 (e.g., metal-siliciding of the layer 50) as shown in the process of FIG. 11B.

As in the processes of FIG. 6A and FIG. 6B, taper angles do not occur easily in the holes H1 due to the patterning of the layers 50 and 51 including silicon. Thereby, for the columnar portions CL, the connection portions CP (the contacts) can be formed so that the connection to the main body portions CB (the channels) is easy. Also, compared to a contact having a tapered configuration, it is unnecessary for the width of the connection portion CP at the upper surface to be large because the thickness in the Y-direction of the connection portion CP is substantially constant toward the lower layers (in the −Z direction). Accordingly, the distance (the distance in the Y-direction) between the mutually-adjacent contacts can be short; therefore, the pitch of the memory holes is reduced easily; and the memory cell is downscaled easily.

In the semiconductor memory device 1 of the embodiment, the trench 91 is formed by removing the layers 50 and 51 as shown in the process of FIG. 10B. Also, the insulating portion 21a is formed as a portion of the inter-layer insulating layer 21 inside the trench 91 as shown in the process of FIG. 13A. The electrode layer 11a (e.g., the drain-side select gate) is divided in the Y-direction by the insulating portion 21a.

As in the process of FIG. 10B, a taper angle does not occur easily in the trench 91 due to the patterning of the layers 50 and 51 including silicon. Thereby, as in the process of FIG. 13A, compared to a trench having a tapered configuration, the breakdown voltage between the mutually-adjacent electrode layers 11a having the insulating portion 21a interposed can be high because the insulating portion 21a inside the trench 91 is formed so that the thickness in the Y-direction is substantially constant toward the lower layers (in the −Z direction).

According to the embodiment, a method for manufacturing a semiconductor memory device is provided in which the memory cells are downscaled.

### Second Embodiment

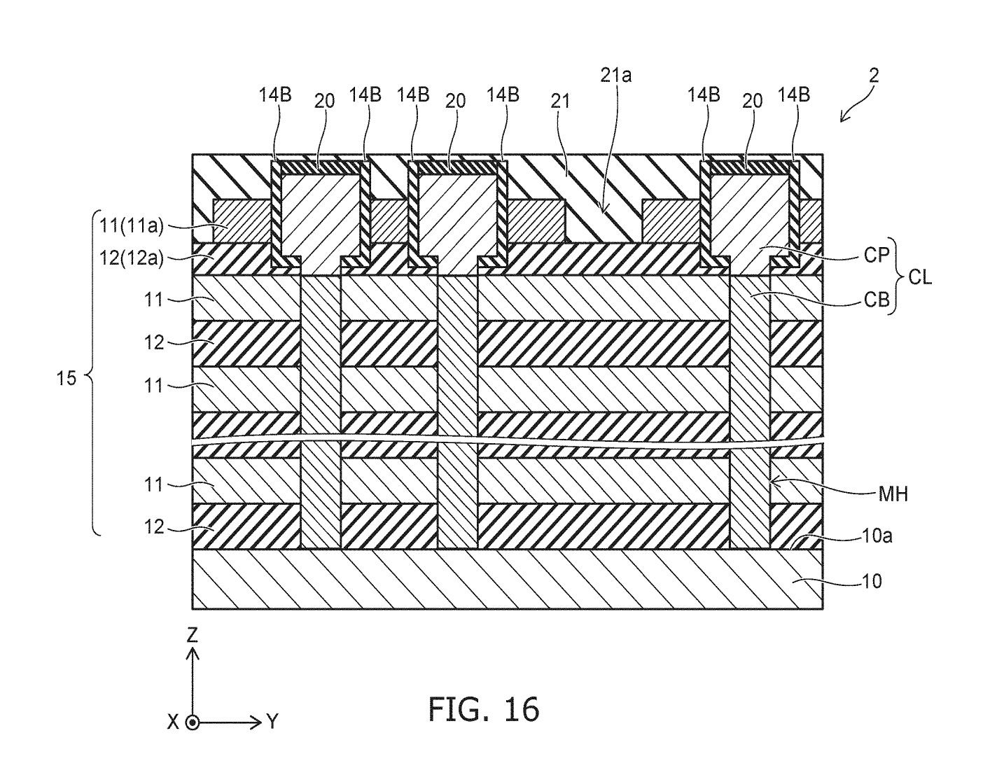

FIG. 16 is a cross-sectional view showing a semiconductor memory device 2.

The region shown in FIG. 16 corresponds to the region shown in FIG. 2.

The semiconductor memory device 2 according to the embodiment differs from the semiconductor memory device 1 of the first embodiment in that the insulating film 14A is not provided; and the formation position of the insulating film 14B is different. Otherwise, the configuration is the same as that of the first embodiment; and a detailed description is therefore omitted.

As shown in FIG. 16, the stacked body 15, the columnar portions CL, the insulating portion 21a, and the insulating member 18 (referring to FIG. 1) are provided in the semiconductor memory device 2. The columnar portion CL includes the main body portion CB and the connection portion CP.

The insulating film 14B is positioned between the connection portion CP of the columnar portion CL and the insulating layer 12a of the stacked body 15 and between the connection portion CP of the columnar portion CL and the electrode layer 11a of the stacked body 15 in the Y-direction. The insulating film 14B is positioned also between the connection portion CP and the insulating layer 12a in the Z-direction. For example, the insulating film 14B covers a portion of the side surface and the bottom surface of the connection portion CP; and the configuration of the insulating film 14B is an L-shaped configuration when viewed from the X-direction.

A method for manufacturing the semiconductor memory device according to the embodiment will now be described.

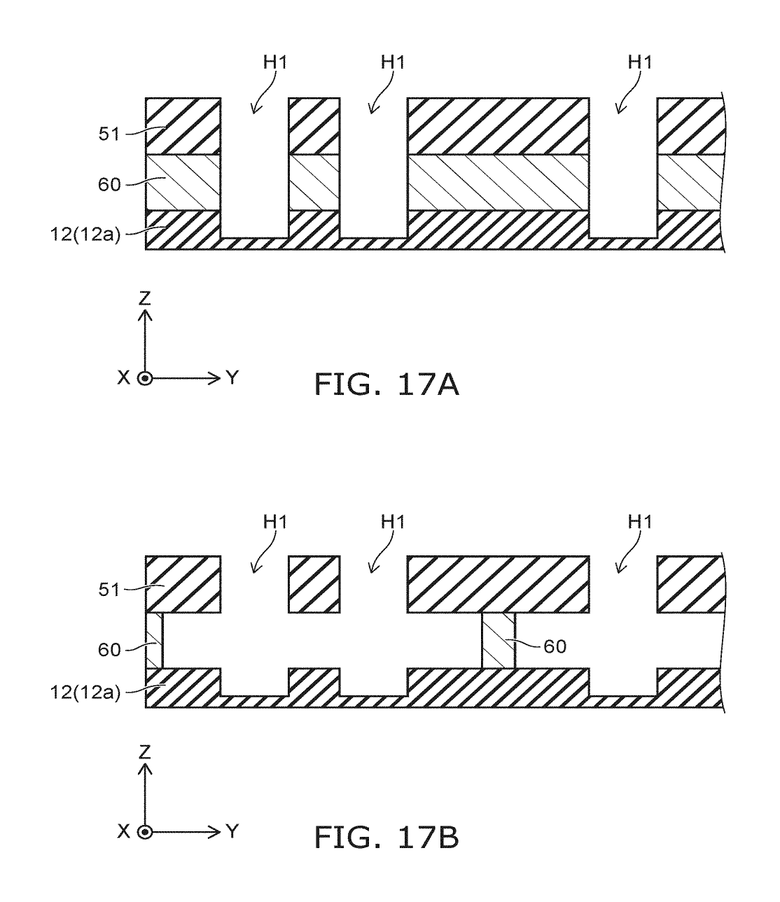

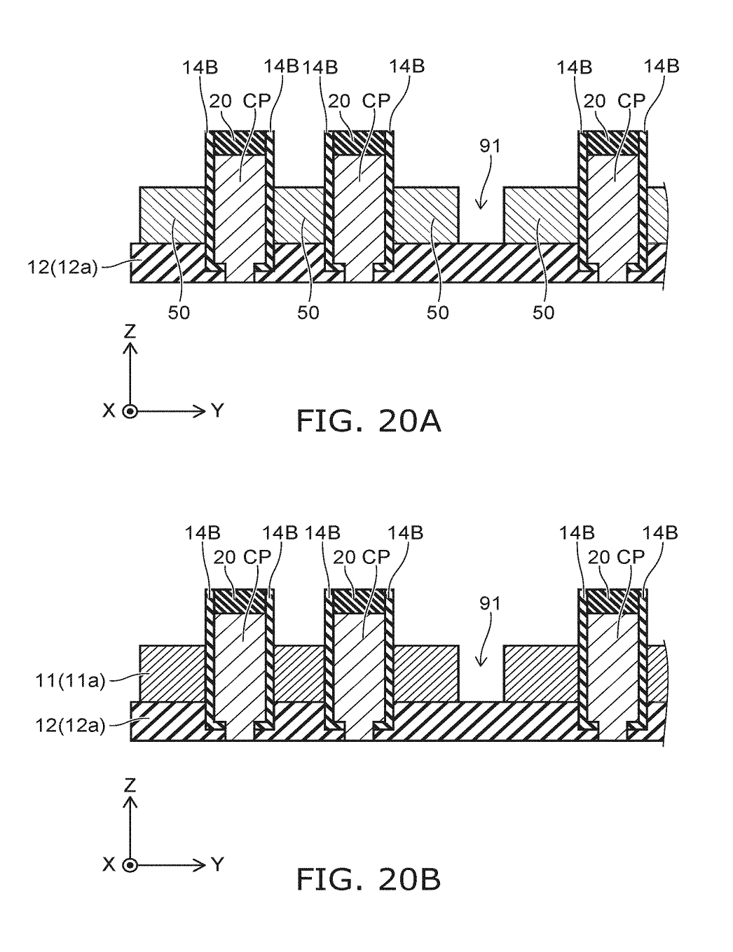

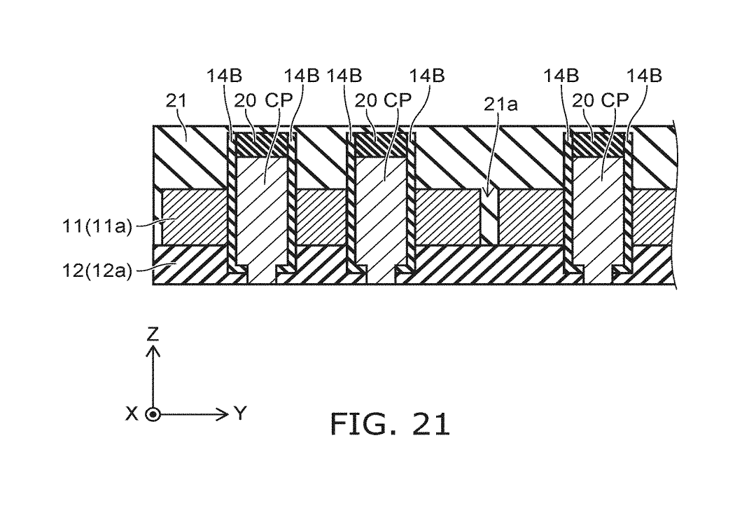

FIG. 17A and FIG. 17B to FIG. 20A, FIG. 20B, and FIG. 21 are drawings showing the method for manufacturing the semiconductor memory device 2. The region shown in FIG. 17A and FIG. 17B to FIG. 20A, FIG. 20B, and FIG. 21 is a portion of the region shown in FIG. 16 and corresponds to the portion of the insulating layer 12a and above.

The formation processes of the portion of the insulating layer 12a and above and the connection portions CP of the columnar portions CL of the semiconductor memory device 2 will now be described using FIG. 17A and FIG. 17B to FIG. 20A, FIG. 20B, and FIG. 21. The formation processes of the portion below the insulating layer 12a and the main body portions CB of the columnar portions CL are the same as those of the first embodiment; and a detailed description is therefore omitted.

The portion below the insulating layer 12a and the main body portions CB of the columnar portions CL are formed; subsequently, as shown in FIG. 17A by, for example, CVD, the insulating layer 12a is formed on the stacked body and the main body portions CB of the columnar portions CL; and a layer 60 is formed on the insulating layer 12a. For example, the insulating layer 12a is formed of silicon oxide; and the layer 60 is formed of silicon germanium (SiGe). Subsequently, the layer 51 is formed on the layer 60. The layer 51 is formed of silicon nitride.

Continuing, the holes H1 are formed in the insulating layer 12a, the layer 60, and the layer 51 by etching such as RIE, etc. The holes H1 extend in the Z-direction, pierce the layer 60 and the layer 51, and reach the insulating layer 12a. The holes H1 are positioned directly above the main body portions CB of the columnar portions CL.

Then, as shown in FIG. 17B, the layer 60 is selectively removed by performing wet etching via the holes H1. By selectively removing the layer 60, a portion of the holes H1 is widened in the X-direction and the Y-direction. A portion of the layer 60 remains without being removed.

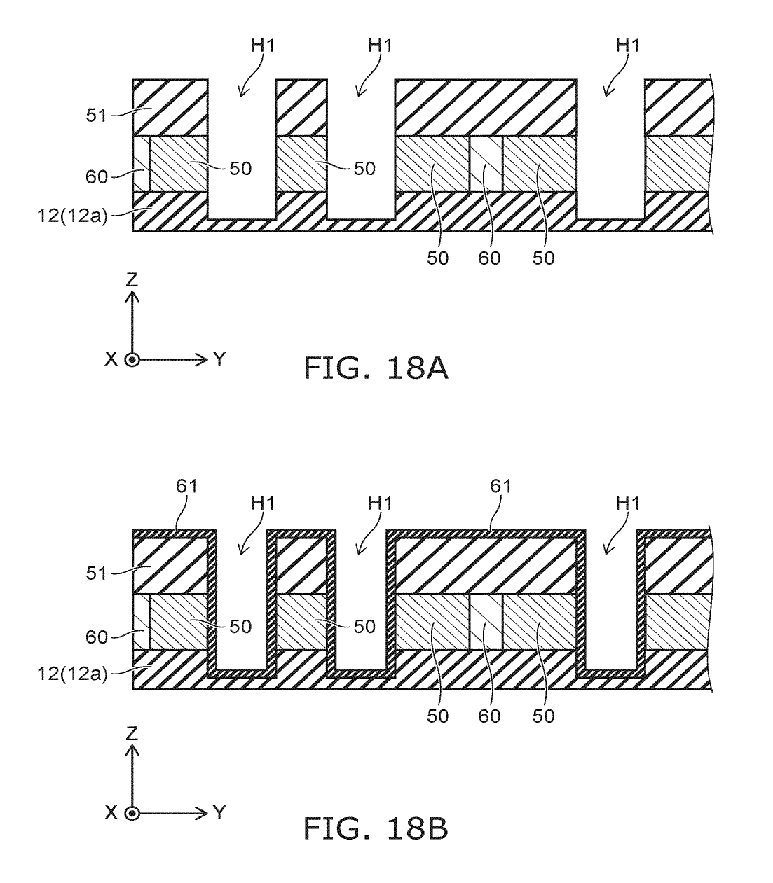

Continuing as shown in FIG. 18A, the layer 50 is formed inside a recess on the insulating layer 12a via the holes H1 by, for example, CVD. For example, the layer 50 is formed of amorphous silicon. Thereby, the layer 50 is filled into the holes H1 widened in the X-direction and the Y-direction in the process of FIG. 17B.

Then, as shown in FIG. 18B, an insulating film 61 is formed on the layers 50 and 51 and the insulating layer 12a inside the holes H1 by, for example, ALD. The insulating film 61 is formed also on the layer 51. The insulating film 61 is formed of, for example, silicon oxide. Although the insulating film 61 is formed also on the insulating layer 12a in the example of FIG. 18B, the insulating film 61 may be formed selectively on the layers 50 and 51 inside the holes H1. That is, the insulating film 61 may be formed only on the side surface of the layer 50 and on the side surface of the layer 51 inside the holes H1.

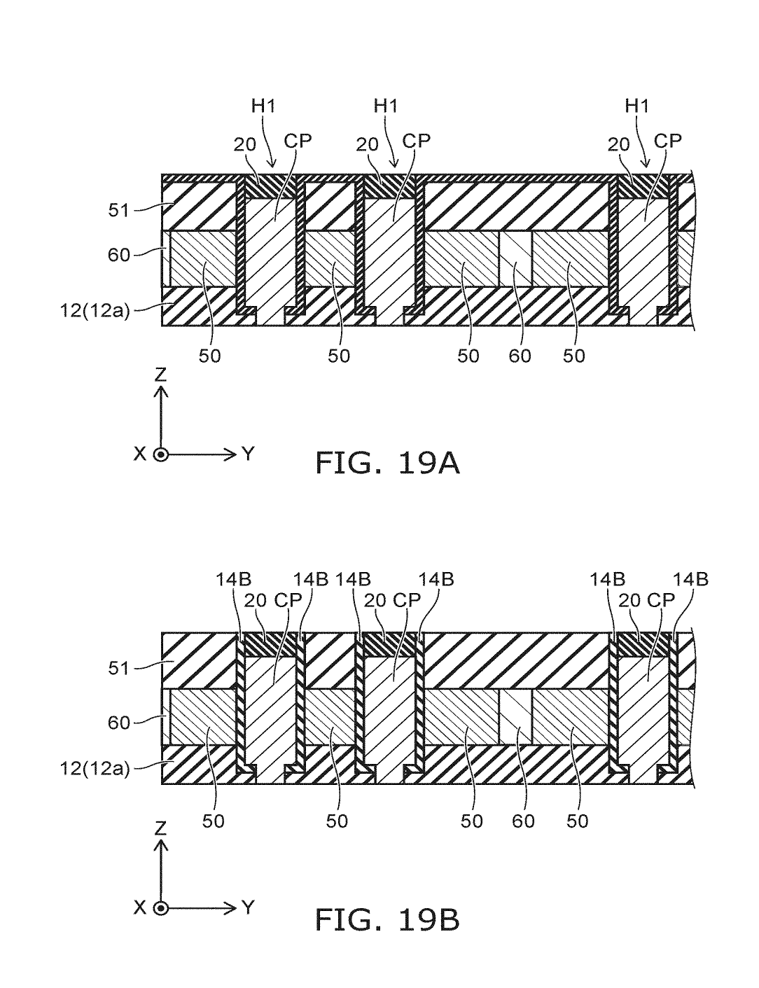

Continuing as shown in FIG. 19A, a portion of the insulating film 61 and a portion of the insulating layer 12a are removed from the bottom surfaces of the holes H1 by etching such as RIE, etc. Thereby, the holes H1 pierce the insulating film 61 and the insulating layer 12a and reach the main body portions CB of the columnar portions CL. Continuing, the connection portions CP are formed inside the holes H1. Subsequently, the insulating film 20 is formed on the connection portions CP inside the holes H1.

Then, as shown in FIG. 19B, the insulating film 61 that is on the layer 51 is removed by etching such as RIE, etc. Thereby, the insulating film 14B is formed. A portion of the insulating film 20 is removed by the etch-back.

Continuing as shown in FIG. 20A by, for example, wet etching, the layer 51 that is positioned on the layers 50 and 60 is removed; subsequently, the layer 60 that is positioned on the insulating layer 12a is removed. The layer 60 that is the layer 51 that is positioned on the layer 50 and the layer 60 that is positioned on the side surface of the layer 50 are selectively removed due to the etching selectivity between the layer 50 (the silicon layer) and the layer 51 (the silicon nitride layer) and between the layer 50 (the silicon layer) and the layer 60 (the silicon germanium layer). Also, the upper surface of the layer 50 is exposed by the removal of the layer 51. The layer 60 that is removed in the process of FIG. 20A corresponds to the portion (the remaining portion) remaining without being removed in the process of FIG. 17B. The trench 91 is formed by removing the layer 60 positioned on the side surface of the layer 50. The trench 91 extends in the X-direction and is formed to divide the layer 50 in the Y-direction.

Then, as shown in FIG. 20B, a metal silicide is formed by forming a metal such as tungsten, etc., on the exposed upper surface of the layer 50 and by subsequently causing the metal to react with the silicon of the layer 50 by performing heat treatment. Thereby, the electrode layer 11 (11a) is formed.

Continuing, after the formation of the metal silicide, the metal that did not react with the silicon of the layer 50 is removed by a chemical liquid. An insulating film may be formed on the side surface of the layer 50 and on the exposed side surface of the insulating film 14B between the processes FIG. 20A and FIG. 20B.

Here, for example, in the case where the number of the columnar portions CL is reduced as shown in FIG. 14B, there are cases where the layer 60 remains in the portions shown by the regions R2 in FIG. 14B without being removed by the wet etching via the holes H1 in the process of FIG. 17B. In such a case, after the process of FIG. 20A, the layer 50 that is on the insulating layer 12a and the layer 60 that remains in the regions R2 are formed; and the electrode layer 11 (11a) includes a metal silicide and a reaction product of the layer 60 and a metal due to the processing of the layer 50 (e.g., the metal-siliciding of the layer 50) in the process of FIG. 20B. For example, the electrode layer 11 (11a) includes a metal silicide and a metal silicide germanide.

Then, as shown in FIG. 21, the inter-layer insulating layer 21 is formed to cover the electrode layer 11 (11a) and the columnar portion CL. The inter-layer insulating layer 21 is formed also inside the trench 91 as the insulating portion 21a. Subsequently, the stacked body 15 (referring to FIG. 16) is formed by replacing, with the electrode layers 11, the sacrificial layers 55 of the stacked body 15a formed in the portion below the insulating layer 12a via the slits 90 (referring to FIG. 1 and FIG. 4). Subsequently, for example, as shown in FIG. 13B, the bit lines BL are formed on the connection portions CP.

Thus, the semiconductor memory device 2 according to the embodiment is manufactured.

Effects of the embodiment will now be described.

In the method for manufacturing the semiconductor memory device 2 of the embodiment, compared to the method for manufacturing the semiconductor memory device 1 such as that shown in FIG. 6A and FIG. 6B, FIG. 7, FIG. 8A and FIG. 8B to FIG. 11A and FIG. 11B, FIG. 12, FIG. 13A, and FIG. 13B, the formation process of the insulating film 52 such as that of FIG. 8A can be omitted; therefore, a reduction of the number of processes can be realized.

Otherwise, the effects of the embodiment are the same as the effects of the first embodiment.

### Third Embodiment

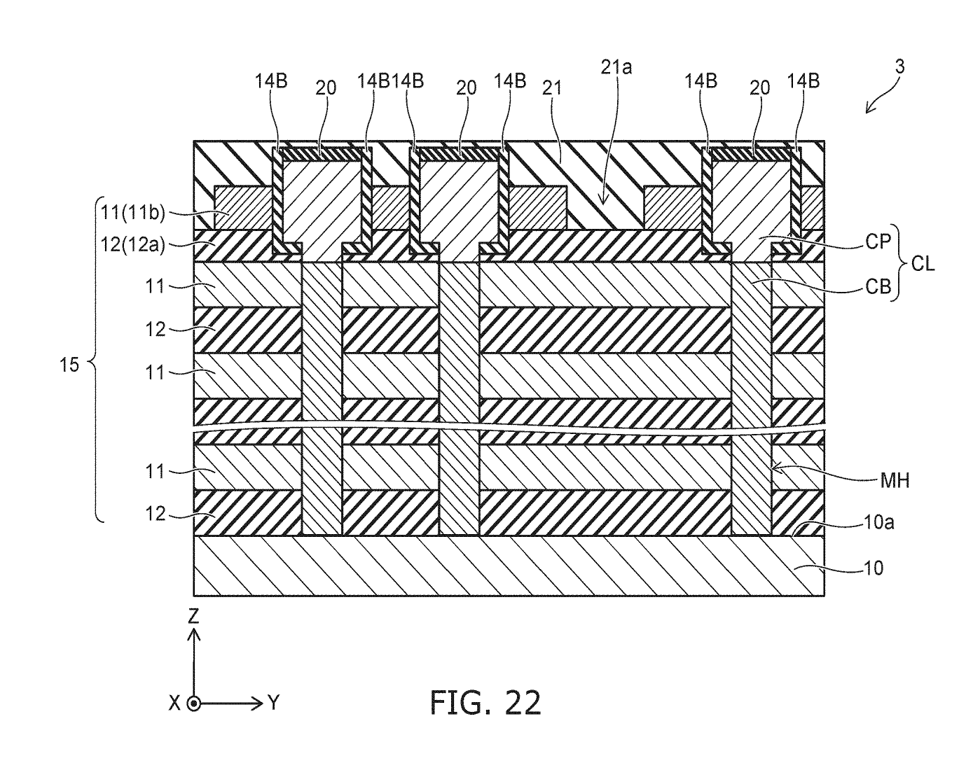

FIG. 22 is a cross-sectional view showing a semiconductor memory device 3.

The region shown in FIG. 22 corresponds to the region shown in FIG. 2.

The semiconductor memory device 3 according to the embodiment differs from the semiconductor memory device 1 of the first embodiment in that the insulating film 14A is not provided; the position where the insulating film 14B is formed is different; and an electrode layer 11b is provided instead of the electrode layer 11a. Otherwise, the configuration is the same as that of the first embodiment; and a detailed description is therefore omitted.

As shown in FIG. 22, the stacked body 15, the columnar portions CL, the insulating portion 21a, and the insulating member 18 (referring to FIG. 1) are provided in the semiconductor memory device 3.

The stacked body 15 includes the multiple electrode layers 11 and the multiple insulating layers 12. For example, among the multiple electrode layers 11 of the stacked body 15, the source-side select gate corresponds to the electrode layer 11 of the lowermost layer; the drain-side select gate corresponds to the electrode layer 11 (11b) of the uppermost layer; and the word lines correspond to the electrode layers 11 other than the electrode layer 11 of the lowermost layer and the electrode layer 11 (11b) of the uppermost layer. The electrode layer 11 (11b) of the uppermost layer of the multiple electrode layers 11 includes a metal such as tungsten, etc.

The insulating film 14B is positioned between the connection portion CP of the columnar portion CL and the insulating layer 12a of the stacked body 15 and between the connection portion CP of the columnar portion CL and the electrode layer 11b of the stacked body 15 in the Y-direction and is positioned between the connection portion CP and the insulating layer 12a in the Z-direction.

A method for manufacturing the semiconductor memory device according to the embodiment will now be described.

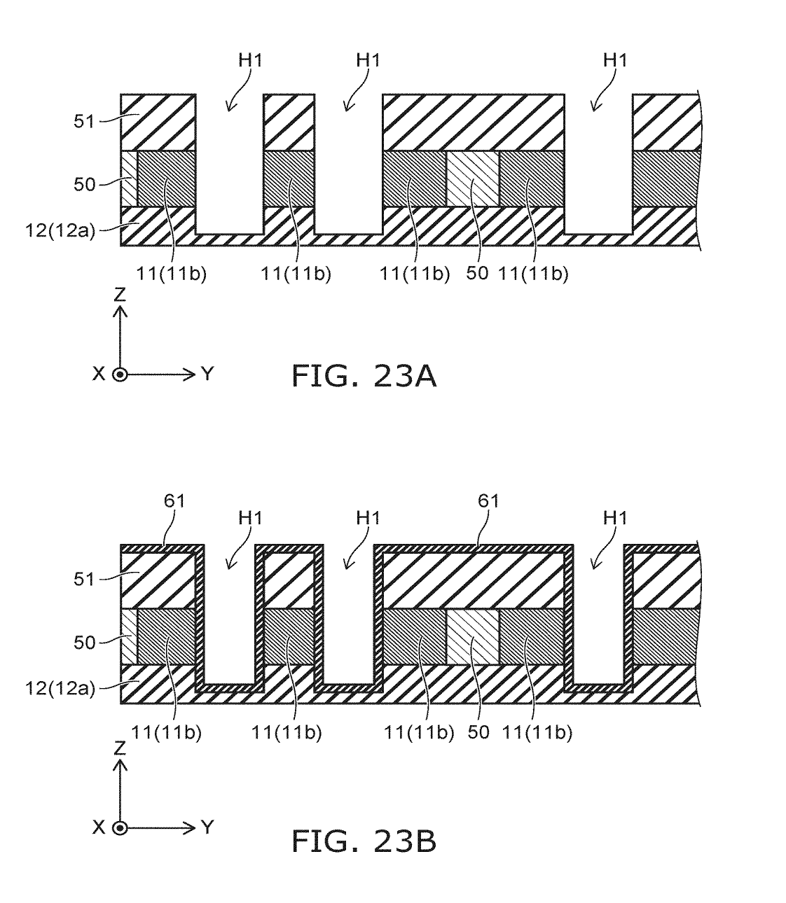

FIG. 23A and FIG. 23B to FIG. 25A and FIG. 25B are drawings showing the method for manufacturing the semiconductor memory device 3. The region shown in FIG. 23A and FIG. 23B to FIG. 25A and FIG. 25B is a portion of the region shown in FIG. 22 and corresponds to the portion of the insulating layer 12a and above.

The formation processes of the portion of the insulating layer 12a and above and the connection portions CP of the columnar portions CL of the semiconductor memory device 3 will now be described using FIG. 23A and FIG. 23B to FIG. 25A and FIG. 25B. The formation processes of the portion below the insulating layer 12a and the main body portions CB of the columnar portions CL are the same as those of the first embodiment; and a detailed description is therefore omitted.

Also, the process of forming the holes H1 (the process of FIG. 6A) and the process of selectively removing the layer 50 (the process of FIG. 6B) are the same as those of the first embodiment; and a detailed description and drawings are therefore omitted.

The layer 50 is selectively removed via the holes H1 as in the process of FIG. 6B; subsequently, as shown in FIG. 23A, the electrode layer 11 (11b) is formed by filling a metal such as tungsten, etc., into a recess on the insulating layer 12a via the holes H1 by, for example, CVD. Thereby, the electrode layer 11b is formed inside the holes H1 widened in the X-direction and the Y-direction in the process of FIG. 6B.

Then, as shown in FIG. 23B, the insulating film 61 is formed on the layer 51, the electrode layer 11b, and the insulating layer 12a inside the holes H1 by, for example, ALD. The insulating film 61 is formed also on the layer 51. The insulating film 61 is formed of, for example, silicon oxide.

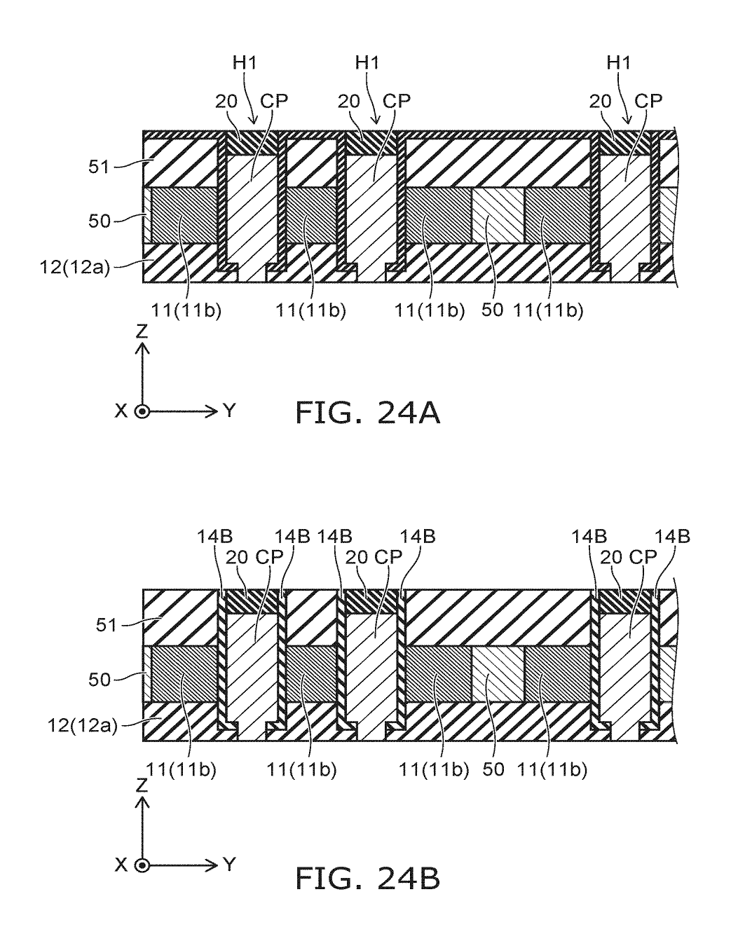

Continuing as shown in FIG. 24A, a portion of the insulating film 61 and a portion of the insulating layer 12a are removed from the bottom surfaces of the holes H1. Thereby, the holes H1 pierce the insulating film 61 and the insulating layer 12a and reach the main body portions CB of the columnar portions CL. Continuing, the connection portions CP are formed inside the holes H1. Subsequently, the insulating film 20 is formed on the connection portions CP inside the holes H1.

Continuing as shown in FIG. 24B, the insulating film 61 that is on the layer 51 is removed. Thereby, the insulating film 14B is formed. A portion of the insulating film 20 also is removed by the etch-back.

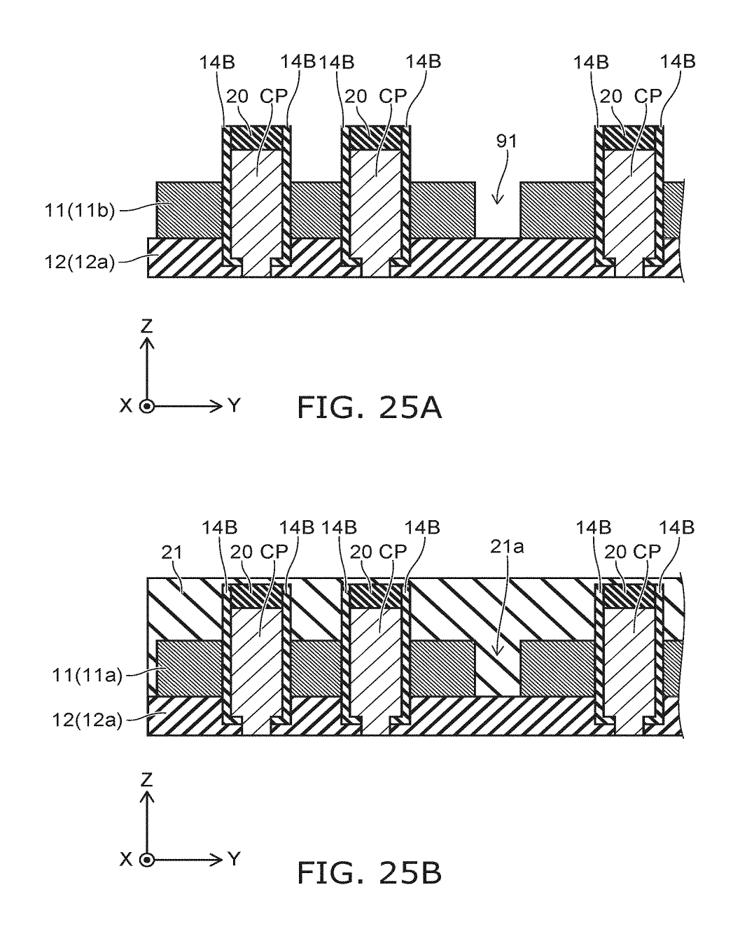

Then, as shown in FIG. 25A by, for example, wet etching, the electrode layer 11b and the layer 51 positioned on the layer 50 are removed; subsequently, the layer 50 that is positioned on the insulating layer 12a is removed. The layer 51 that is positioned on the electrode layer 11b and the layer 50 that is positioned on the side surface of the electrode layer 11b are selectively removed due to the etching selectivity between the electrode layer 11b (the tungsten layer) and the layer 51 (the silicon nitride layer) and between the electrode layer 11b (the tungsten layer) and the layer 50 (the silicon layer). The layer 50 that is removed in the process of FIG. 25A corresponds to the portion (the remaining portion) remaining without being removed in the process of FIG. 6B. The trench 91 is formed by removing the layer 50 that is positioned on the side surface of the electrode layer 11b. The trench 91 extends in the X-direction and is formed to divide the electrode layer 11b in the Y-direction.

Here, for example, in the case where the number of the columnar portions CL is reduced as shown in FIG. 14B, there are cases where the layer 50 remains in the portions shown by the regions R2 in FIG. 14B without being removed by the wet etching via the holes H1 in the process of FIG. 6B. In such a case, after the process of FIG. 25A, for example, the tungsten layer that is on the insulating layer 12a and the layer 50 that remains in the regions R2 are formed; and the electrode layer 11 (11b) includes, for example, the tungsten layer and the layer 50. For example, the electrode layer 11 (11b) includes tungsten and amorphous silicon.

Then, as shown in FIG. 25B, the inter-layer insulating layer 21 is formed to cover the electrode layer 11 (11b) and the columnar portions CL. The inter-layer insulating layer 21 is formed also inside the trench 91 as the insulating portion 21a. Subsequently, the stacked body 15 (referring to FIG. 22) is formed by replacing, with the electrode layers 11, the sacrificial layers 55 of the stacked body 15a formed in the portion below the insulating layer 12a via the slits 90 (referring to FIG. 1). Subsequently, for example, the bit lines BL are formed on the connection portions CP as shown in FIG. 13B.

Thus, the semiconductor memory device 3 according to the embodiment is manufactured.

In the method for manufacturing the semiconductor memory device 3 of the embodiment, compared to the method for manufacturing the semiconductor memory device 1 such as that shown in FIG. 6A and FIG. 6B, FIG. 7, FIG. 8A and FIG. 8B to FIG. 11A and FIG. 11B, FIG. 12, FIG. 13A, and FIG. 13B, the formation process of the insulating film 52 such as that of FIG. 8A and the formation process of the metal silicide such as that of FIG. 11B can be omitted; therefore, a reduction of the number of processes can be realized.

Otherwise, the effects of the embodiment are the same as the effects of the first embodiment.

### Fourth Embodiment

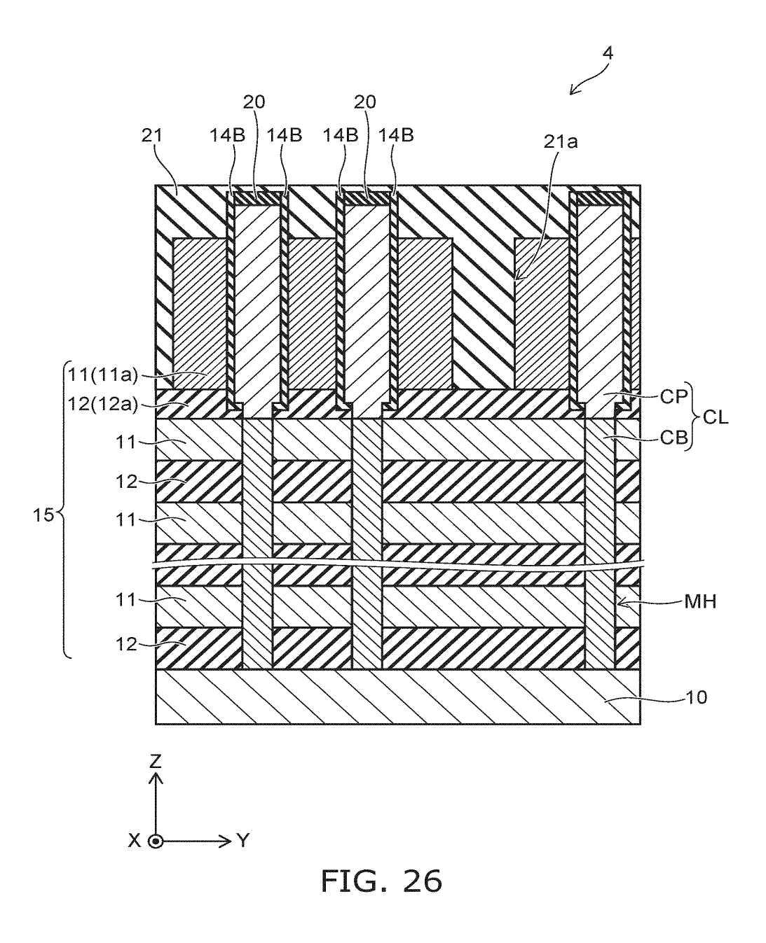

FIG. 26 is a cross-sectional view showing a semiconductor memory device 4.

The region shown in FIG. 26 corresponds to the region shown in FIG. 2.

The semiconductor memory device 4 according to the embodiment differs from the semiconductor memory device 1 of the first embodiment in that the insulating film 14A is not provided; the formation position of the insulating film 14B is different; and the thickness of the electrode layer 11a is different. Otherwise, the configuration is the same as that of the first embodiment; and a detailed description is therefore omitted.

As shown in FIG. 26, the stacked body 15, the columnar portions CL, the insulating portion 21a, and the insulating member 18 (referring to FIG. 1) are provided in the semiconductor memory device 4. The columnar portion CL includes the main body portion CB and the connection portion CP.

The insulating film 14B is positioned between the connection portion CP of the columnar portion CL and the insulating layer 12a of the stacked body 15 and between the connection portion CP of the columnar portion CL and the electrode layer 11a of the stacked body 15 in the Y-direction and is positioned between the connection portion CP and the insulating layer 12a in the Z-direction.

A method for manufacturing the semiconductor memory device according to the embodiment will now be described.

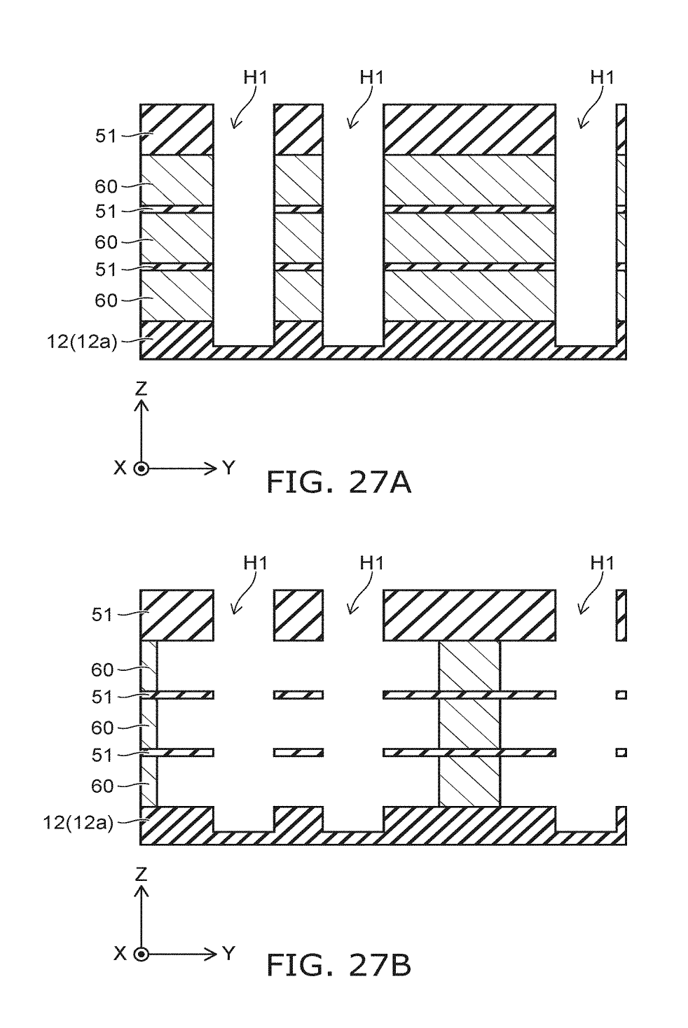

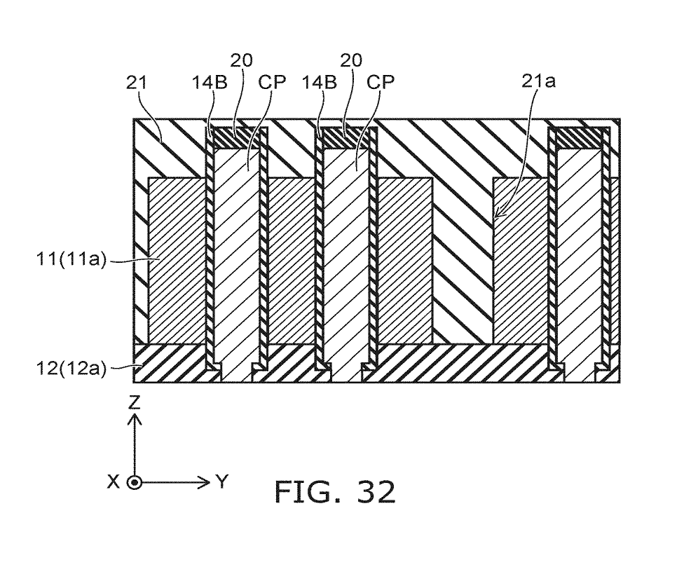

FIG. 27A and FIG. 27B to FIG. 31A and FIG. 31B, and FIG. 32 are drawings showing the method for manufacturing the semiconductor memory device 4. The region shown in FIG. 27A and FIG. 27B to FIG. 31A and FIG. 31B, and FIG. 32 is a portion of the region shown in FIG. 26 and corresponds to the portion of the insulating layer 12a and above.

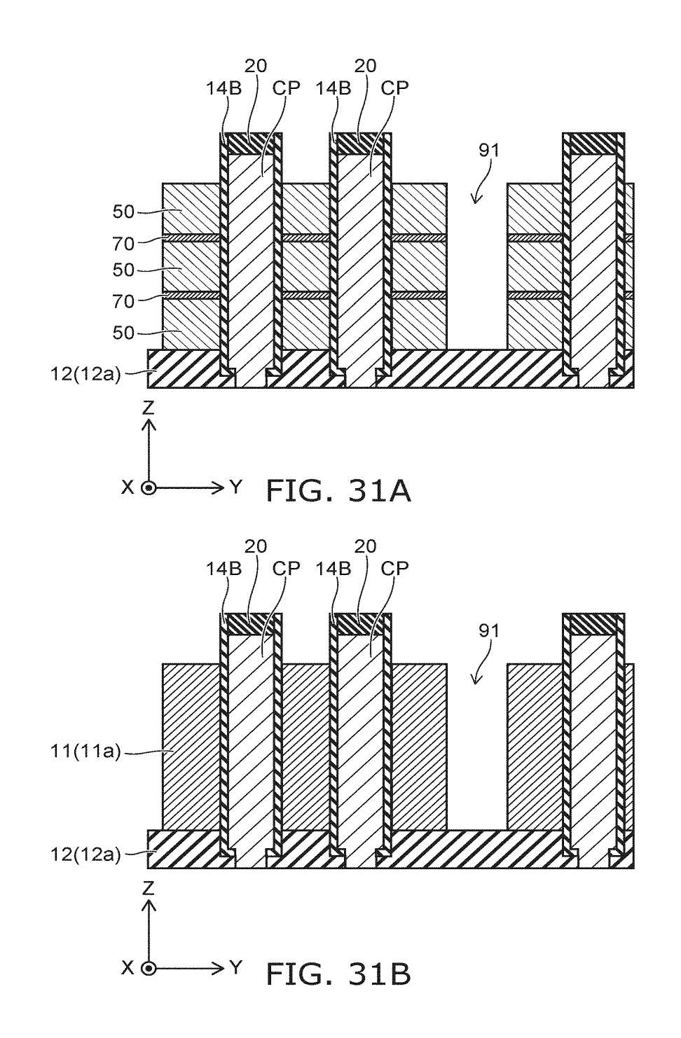

The formation processes of the portion of the insulating layer 12a and above and the connection portions CP of the columnar portions CL of the semiconductor memory device 4 will now be described using FIG. 27A and FIG. 27B to FIG. 31A, FIG. 31B, and FIG. 32. The formation processes of the portion below the insulating layer 12a and the main body portions CB of the columnar portions CL are the same as those of the first embodiment; and a detailed description is therefore omitted.

The portion below the insulating layer 12a and the main body portions CB of the columnar portions CL are formed; subsequently, as shown in FIG. 27A, the insulating layer 12a is formed on the stacked body and the main body portions CB of the columnar portions CL. For example, the insulating layer 12a is formed of silicon oxide. Continuing, the layer 60 and the layer 51 are formed alternately on the insulating layer 12a by, for example, CVD. For example, the layer 60 is formed of silicon germanium; and the layer 51 is formed of silicon nitride.

Although the number of stacks is three layers each for the layers 60 and 51 stacked alternately on the insulating layer 12a in the example of FIG. 27A, the numbers of stacks of the layers 60 and 51 are arbitrary. For example, the thickness in the Z-direction is substantially constant for each of the layers 60. For example, the thickness in the Z-direction of the layer 51 of the uppermost layer is thicker than the thicknesses in the Z-direction of the other layers 51.

Continuing, the holes H1 are formed in the insulating layer 12a, the layers 60, and the layers 51 by etching such as RIE, etc. The holes H1 extend in the Z-direction, pierce the layers 60 and the layers 51, and reach the insulating layer 12a. The holes H1 are positioned directly above the main body portions CB of the columnar portions CL.

Then, as shown in FIG. 27B, the layers 60 are selectively removed by performing wet etching via the holes H1. A portion of the holes H1 is widened in the X-direction and the Y-direction by selectively removing the layers 60. A portion of the layers 60 remains without being removed.

Here, in the case where the layers 60 are formed of silicon germanium, the proportion of the layers 60 remaining in the process of FIG. 27B can be changed by changing the concentration of germanium (Ge) for each of the layers 60. For example, although the number of stacks of the layers 60 is three layers, the concentration of germanium of the middle layer 60 between the lower layer and the upper layer is set to be lower than those of the layer 60 of the lower layer and the layer 60 of the upper layer. In the case where the concentration of germanium is low, the etching rate is low and the layer 60 is not etched easily; therefore, the thickness in the Y-direction of the layer 60 remaining without being removed is large for the middle layer 60. That is, the thickness in the Y-direction of the middle layer 60 remaining without being removed is thicker than the thickness in the Y-direction of the layer 60 of the lower layer and the layer 60 of the upper layer remaining without being removed. Accordingly, in such a case, compared to FIG. 27B, the strength of the structure body that includes the insulating layer 12a, the layers 60, and the layers 51 is large; and the risk of the collapse can be suppressed.

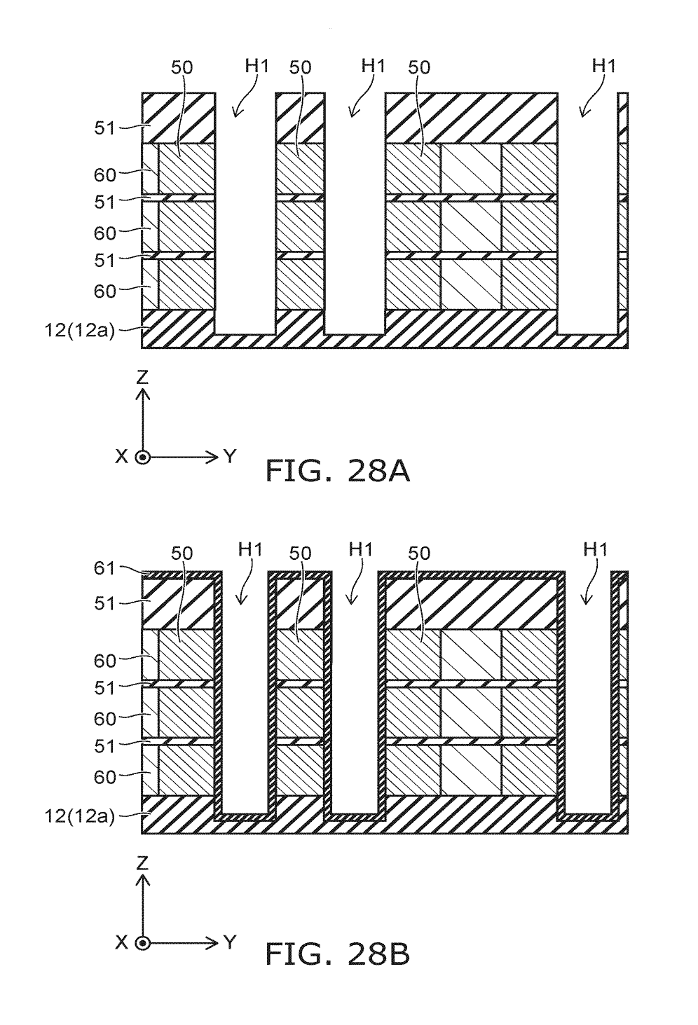

Then, as shown in FIG. 28A, the layers 50 are formed via the holes H1 inside the portions where the layers 60 are selectively removed in the process of FIG. 27B by, for example, CVD. For example, the layers 50 are formed of amorphous silicon. Thereby, the layers 50 are filled into the holes H1 widened in the X-direction and the Y-direction in the process of FIG. 27B.

Continuing as shown in FIG. 28B, the insulating film 61 is formed on the layers 50 and 51 and the insulating layer 12a inside the holes H1 by, for example, ALD. The insulating film 61 is formed also on the layer 51 of the uppermost layer. The insulating film 61 is formed of, for example, silicon oxide.

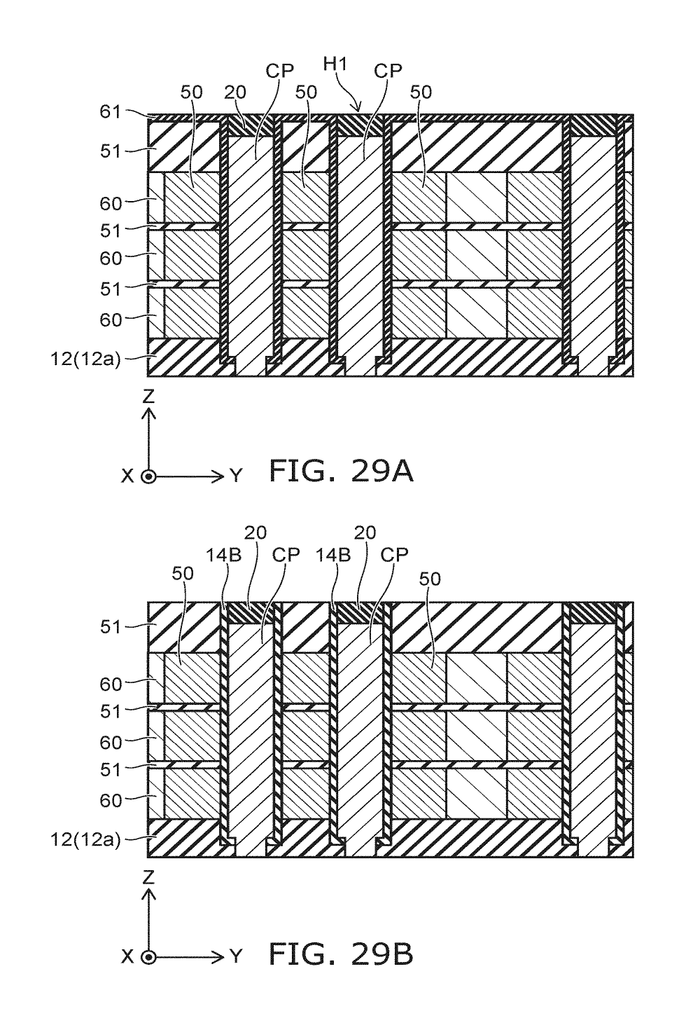

Then, as shown in FIG. 29A, a portion of the insulating film 61 and a portion of the insulating layer 12a are removed from the bottom surfaces of the holes H1 by etching such as RIE, etc. Thereby, the holes H1 pierce the insulating film 61 and the insulating layer 12a and reach the main body portions CB of the columnar portions CL. Continuing, the connection portions CP are formed inside the holes H1. Subsequently, the insulating film 20 is formed on the connection portions CP inside the holes H1.

Then, as shown in FIG. 29B, the insulating film 61 that is on the layer 51 is removed by etching such as RIE, etc. Thereby, the insulating film 14B is formed. A portion of the insulating film 20 also is removed by the etch-back.

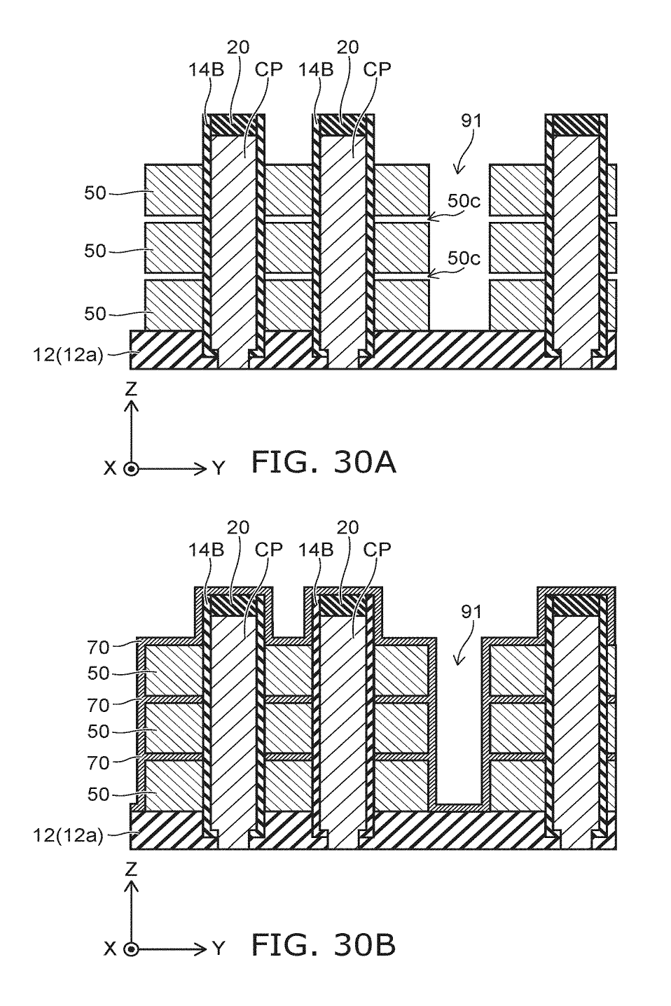

Continuing as shown in FIG. 30A by, for example, wet etching, the layer 51 of the uppermost layer that is positioned on the layers 50 and 60 is removed; subsequently, the layers 60 and 51 that are positioned on the insulating layer 12a and the layer 51 that is positioned between the layers 50 are removed. The layers 51 and 60 are removed due to the etching selectivity between the layer 50 (the silicon layer) and the layer 51 (the silicon nitride layer) and between the layer 50 (the silicon layer) and the layer 60 (the silicon germanium layer). The trench 91 is formed by removing the layers 51 and 60. The trench 91 extends in the X-direction, pierces the layers 50 in the Z-direction, and reaches the insulating layer 12a. Also, gaps 50c are formed between the layers 50 by removing the layers 51 positioned between the layers 50.

Then, as shown in FIG. 30B by, for example, CVD, a layer 70 is formed by filling, via the trench 91, amorphous silicon or the like into the gaps 50c formed between the layers 50. The layer 70 is formed also on the inner wall surface and the bottom surface of the trench 91. The layer 70 is formed also on the layer 50 of the uppermost layer and on the insulating film 14B and the insulating film 20 protruding from the layer 50 of the uppermost layer.

Continuing as shown in FIG. 31A, the layer 70 that is on the bottom surface of the trench 91 is removed by etching such as RIE, etc. The layer 70 that is formed on the inner wall surface of the trench 91, on the layer 50 of the uppermost layer, and on the insulating film 14B and the insulating film 20 protruding from the layer 50 of the uppermost layer also is etched and removed. A portion of the layers 50 is exposed by removing a portion of the layer 70.

Then, as shown in FIG. 31B, a metal silicide is formed by forming a metal such as tungsten, etc., on the exposed upper surface of the layer 50 and subsequently causing the metal to react with the silicon of the layers 50 by performing heat treatment. In the case where the layer 70 is formed of silicon, a metal silicide is formed by the metal reacting with the silicon of the layer 70. That is, the electrode layer 11 (11a) is formed by the layers 50 and 70 becoming metal silicides by the silicon of the stacked body reacting with the metal. Continuing, after the formation of the metal silicide, the metal that did not react with the silicon of the layers 50 and 70 is removed using a chemical liquid.

Here, for example, in the case where the number of the columnar portions CL is reduced as shown in FIG. 14B, there are cases where the layers 60 remain in the portions shown by the regions R2 in FIG. 14B without being removed by the wet etching via the holes H1 in the process of FIG. 27B. In such a case, in the process of FIG. 31A, the layers 50, the layer 70, and the layers 60 that remain in the regions R2 are formed on the insulating layer 12a; and the electrode layer 11 (11a) includes a metal silicide and a reaction product of the metal and the layers 60 due to the processing of the layers 50 and 70 (e.g., the metal-siliciding of the layers 50 and 70) in the process of FIG. 31B. For example, the electrode layer 11 (11a) includes a metal silicide and a metal silicide germanide.

Continuing as shown in FIG. 32, the inter-layer insulating layer 21 is formed to cover the electrode layer 11 (11a) and the columnar portions CL by, for example, CVD. The inter-layer insulating layer 21 is formed of, for example, silicon oxide. The inter-layer insulating layer 21 is formed also inside the trench 91 as the insulating portion 21a. Subsequently, the stacked body 15 (referring to FIG. 26) is formed by replacing, with the electrode layers 11, the sacrificial layers 55 of the stacked body 15a formed in the portion below the insulating layer 12a via the slits 90 (referring to FIG. 1). Subsequently, for example, the bit lines BL are formed on the connection portions CP as shown in FIG. 13B.

Thus, the semiconductor memory device 4 according to the embodiment is manufactured.

Effects of the embodiment will now be described.

In the semiconductor memory device 4 of the embodiment, multiple layers of the layers 60 and 51 including silicon are stacked as shown in the processes of FIG. 27A and FIG. 27B; and subsequently, the holes H1 that pierce the layers 60 and 51 are formed. The connection portions CP of the columnar portions CL are formed inside the holes H1 as shown in the process of FIG. 29A; and the electrode layer 11 (11a) is formed by the processing of the layers 50 and 70 (e.g., the metal-siliciding of the layers 50 and 70) having multiple layers as shown in the process of FIG. 31B. Thereby, the thickness of the electrode layer 11a is formed to be thick; and, for example, the resistance of the drain-side select gate can be lower.

Thus, even in the case where the thickness of the electrode layer 11a is set to be thick, the patterning is not very difficult; and effects similar to those of the first embodiment can be obtained. That is, taper angles do not occur easily in the upper portions of the holes inside the stacked body 15 because the layers 60 and 51 including silicon are patterned as in the processes of FIG. 27A and FIG. 27B. Thereby, the connection portions CP (the contacts) of the columnar portions CL can be formed so that the connection to the main body portions CB (the channels) is easy. Also, the connection portion CP is formed so that the thickness in the Y-direction is substantially constant toward the lower layers (in the −Z direction); therefore, compared to a contact having a tapered configuration, it is unnecessary to form the width of the upper surface to be large. Accordingly, the distance (the distance in the Y-direction) between the mutually-adjacent contacts can be short; therefore, it is easy to reduce the pitch of the memory holes; and the memory cell is downscaled easily.

In the semiconductor memory device 4 of the embodiment as shown in the process of FIG. 30A, the trench 91 that extends in the X-direction is formed through the layers 50 by removing the layers 51 and 60. As shown in the process of FIG. 32, the insulating portion 21a is formed as a portion of the inter-layer insulating layer 21 inside the trench 91. The electrode layer 11a (e.g., the drain-side select gate) is divided in the Y-direction by the insulating portion 21a.

A taper angle does not occur easily in the trench 91 because the layers 60 and 51 including silicon are patterned as in the process of FIG. 30A. Thereby, as in the process of FIG. 32, the insulating portion 21a that is inside the trench 91 is formed so that the thickness in the Y-direction is substantially constant toward the lower layers (in the −Z direction); therefore, compared to a trench having a tapered configuration, the breakdown voltage between the mutually-adjacent electrode layers 11a having the insulating portion 21a interposed can be increased.

According to the embodiment, a method for manufacturing a semiconductor memory device is provided in which the memory cells are downscaled.

Although the case is described in the embodiments recited above where the formation processes of the portion below the insulating layer 12a include forming the stacked body 15a including the insulating layers 12 including silicon oxide and the sacrificial layers 55 including silicon nitride on the substrate 10 and replacing the sacrificial layers 55 with the electrode layers 11, this is not limited thereto. For example, a conductive layer that includes a metal, a metal silicide, etc., may be formed inside the stacked body 15a instead of the sacrificial layer including silicon nitride; and the conductive layer may be used as the electrode layer 11 as-is without replacing the conductive layer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions. Additionally, the embodiments described above can be combined mutually.

What is claimed is:

1. A method for manufacturing a semiconductor memory device, comprising:
forming a stacked body on a substrate by alternately stacking a first insulating layer and a first layer;
forming a plurality of first through-holes in the stacked body, the plurality of first through-holes extending in a stacking direction of the first insulating layer and the first layer;
forming main body portions inside the plurality of first through-holes, each of the main body portions including a charge storage film and a semiconductor portion;
forming a second insulating layer on the stacked body and the plurality of main body portions;
forming a second layer on the second insulating layer;
forming a third layer on the second layer;
forming a plurality of second through-holes in the second layer and the third layer, the plurality of second through-holes extending in the stacking direction, piercing the second layer and the third layer, reaching the second insulating layer, and being positioned directly above the plurality of main body portions;
removing a portion of the second layer to widen diameters of a portion of the plurality of second through-holes;
forming a fourth layer after forming a third insulating layer, the third insulating layer being formed on the second layer and the third layer exposed inside the plurality of second through-holes, the fourth layer being used to form a gate material and being formed inside the portion where the diameters of the plurality of second through-holes are widened;
forming a first insulating film on a side surface of the fourth layer inside the plurality of second through-holes;
after the forming of the first insulating film, removing a portion of the second insulating layer to expose upper surfaces of the plurality of main body portions at bottom portions of the plurality of second through-holes;
forming a plurality of connection portions on the plurality of main body portions by filling a semiconductor material into the plurality of second through-holes; and
after the forming of the plurality of connection portions, removing the third layer and a remaining portion of the second layer, the remaining portion of the second layer not being removed in the removing of the portion of the second layer.

2. The method according to claim 1, further comprising forming an inter-layer insulating layer by filling the inter-layer insulating layer into a portion where the third layer and the remaining portion of the second layer are removed.

3. The method according to claim 1, wherein the portions where the diameters of the plurality of second through-holes are widened communicate with each other in a direction orthogonal to the stacking direction in the removing of the portion of the second layer.

4. The method according to claim 1, wherein the remaining portion of the second layer is formed to extend in a first direction parallel to an upper surface of the substrate in the removing of the portion of the second layer.

5. The method according to claim 4, wherein
the first insulating layer includes silicon oxide,
the first layer includes silicon nitride, and
the method further comprises:
forming a slit in the stacked body, the slit extending in the stacking direction and the first direction;
removing the first layer via the slit; and
forming an electrode layer inside a gap formed by the removing of the first layer.

6. The method according to claim 1, wherein silicon is filled into the plurality of second through-holes in the forming of the plurality of connection portions.

7. The method according to claim 1, wherein
the fourth layer includes silicon, and
the method further comprises:
after the removing of the third layer and the remaining portion of the second layer, removing a portion of the third insulating layer to expose an upper surface of the fourth layer; and
forming a metal on the exposed upper surface of the fourth layer and siliciding the metal by causing a reaction with the silicon inside the fourth layer.

8. A method for manufacturing a semiconductor memory device, comprising:
forming a stacked body on a substrate by alternately stacking a first insulating layer and a first layer;
forming a plurality of first through-holes in the stacked body, the plurality of first through-holes extending in a stacking direction of the first insulating layer and the first layer;
forming main body portions inside the plurality of first through-holes, each of the main body portions including a charge storage film and a semiconductor portion;
forming a second insulating layer on the stacked body and the plurality of main body portions;
forming a second layer on the second insulating layer;
forming a third layer on the second layer;
forming a plurality of second through-holes in the second layer and the third layer, the plurality of second through-holes extending in the stacking direction, piercing the second layer and the third layer, reaching the second insulating layer, and being positioned directly above the plurality of main body portions;
removing a portion of the second layer to widen diameters of a portion of the plurality of second through-holes;
forming a fourth layer inside the portion where the diameters of the plurality of second through-holes are widened, the fourth layer being used to form a gate material;
forming a first insulating film on a side surface of the fourth layer inside the plurality of second through-holes;
after the forming of the first insulating film, removing a portion of the second insulating layer to expose upper surfaces of the plurality of main body portions at bottom portions of the plurality of second through-holes;
forming a plurality of connection portions on the plurality of main body portions by filling a semiconductor material into the plurality of second through-holes; and
after the forming of the plurality of connection portions, removing the third layer and a remaining portion of the second layer selectively with respect to the fourth layer, the remaining portion of the second layer not being removed in the removing of the portion of the second layer.

9. The method according to claim 8, further comprising forming a third insulating layer by filling the third insulating layer into a portion where the third layer and the remaining portion of the second layer are removed.

10. The method according to claim 8, wherein the portions where the diameters of the plurality of second through-holes are widened communicate with each other in a direction orthogonal to the stacking direction in the removing of the portion of the second layer.

11. The method according to claim 10, wherein the remaining portion of the second layer is formed to extend in a first direction parallel to an upper surface of the substrate in the removing of the portion of the second layer.

12. The method according to claim 11, wherein
the first insulating layer includes silicon oxide,
the first layer includes silicon nitride, and
the method further comprises:
forming a slit in the stacked body, the slit extending in the stacking direction and the first direction;
removing the first layer via the slit; and
forming a first electrode layer inside a gap formed by the removing of the first layer.

13. The method according to claim 8, wherein
the second layer includes silicon germanium,
the third layer includes silicon nitride, and
the fourth layer includes silicon or a metal.

14. The method according to claim 8, wherein silicon is filled into the plurality of second through-holes in the forming of the plurality of connection portions.

15. The method according to claim 8, wherein
the fourth layer includes silicon, and
the method further comprises forming a metal on an upper surface of the fourth layer and siliciding the metal by causing a reaction with the silicon inside the fourth layer, the upper surface of the fourth layer being exposed by the selective removing of the third layer and the remaining portion of the second layer.

16. The method according to claim 8, wherein
the fourth layer includes silicon,
a plurality of the second layers is formed with a fifth layer interposed in the forming of the second layer,
the second through-holes are formed in the second layers, the third layer, and the fifth layer in the forming of the second through-holes,
the fifth layer also is removed selectively with respect to the fourth layer in the removing of the third layer and the remaining portions of the second layers, and
the method further comprises:
forming a sixth layer inside a gap formed by the selective removing of the fifth layer, the sixth layer including silicon; and
forming a metal on the sixth layer and the fourth layer exposed by the selective removing of the third layer and the remaining portion of the second layer, and siliciding the metal by causing a reaction with the silicon inside the fourth layer and the sixth layer.

17. A semiconductor memory device, comprising:
a substrate;
a stacked body including a plurality of electrode layers and provided on the substrate, the plurality of electrode layers extending in a first direction parallel to an upper surface of the substrate and being stacked to be separated from each other;
a plurality of columnar portions provided inside the stacked body, each of the plurality of columnar portions including a main body portion and a connection portion, the main body portion including a semiconductor portion extending in a stacking direction of the plurality of electrode layers, the connection portion being provided on the main body portion, at least a portion of the connection portion being positioned inside a first electrode layer of an uppermost layer of the stacked body among the plurality of electrode layers; and
an insulating layer provided on the first electrode layer,
the first electrode layer including a first portion and a second portion opposing each other in a second direction with a portion of the insulating layer interposed, the second direction crossing the first direction and being parallel to the upper surface of the substrate.

18. The device according to claim 17, wherein the portion of the insulating layer extends in the first direction.

19. The device according to claim 17, wherein a charge storage film is formed in the main body portion of the columnar portion between the semiconductor portion and one electrode layer of the plurality of electrode layers other than the first electrode layer.

20. The device according to claim 19, wherein
the connection portion of the columnar portion includes a silicon portion electrically connected to the semiconductor portion, and
the charge storage film is not formed between the first electrode layer and the silicon portion.
